(19) United States
(12) Patent Application Publication
(10) Pub. No.: US 2026/0033075 A1
(43) Pub. Date: Jan. 29, 2026

(54) Display Device

(71) Applicant: LG Display Co., Ltd., Seoul (KR)

(72) Inventor: Sunghyun Jang, Paju-si (KR)

(21) Appl. No.: 19/195,193

(22) Filed: Apr. 30, 2025

(30) Foreign Application Priority Data
Jul. 26, 2024 (KR) 10-2024-0099787

(51) Int. Cl. H10H 29/49; H01L 25/16; H10H 29/41; H10H 29/855

(52) U.S. Cl. CPC H10H 29/49; H01L 25/167; H10H 29/41; H10H 29/8552

(57) ABSTRACT

A display device includes a substrate including a display area and a non-display area; driving chips on the display area; light-emitting elements electrically connected to the driving chips; and a pad on the non-display area and including a pad electrode electrically connected to the light-emitting elements, wherein the display area extends in row and column directions, wherein the display area is divided into block areas in each of both opposing sides around a central column virtual line of the display area, wherein both block areas are arranged in the row direction in a symmetrical manner to each other around the central column virtual line, wherein the block areas are arranged in the column direction, wherein power signals from the pad are directly applied to the driving chips, wherein data and clock signals from the pad are applied to the driving chips of each of the block areas.

### CROSS-REFERENCE TO RELATED APPLICATION

This application claims priority from Republic of Korea Patent Application No. 10-2024-0099787 filed on Jul. 26, 2024, which is hereby incorporated by reference in its entirety.

### FIELD

The present disclosure relates to an apparatus and particularly to, for example, without limitation, a display device.

### DESCRIPTION OF RELATED ART

Display devices are applied to various electronic devices such as a television (TV), mobile phones, laptops, and tablets.

The display device includes an organic light-emitting display device (OLED) that emits light by itself, and a liquid crystal display device (LCD) that requires a separate light source.

Recently, a display device including a light-emitting diode (LED) made of not an organic material, but an inorganic material, has attracted attention as a next-generation display device. Since the light-emitting diode is made of the inorganic material rather than the organic material, the display device including the light-emitting diode may have a faster lighting speed than that of the liquid crystal display device or the organic light-emitting display device, and may have excellent luminous efficiency, and may display an image with high luminance.

### SUMMARY

Other systems, methods, features and advantages will be, or will become, apparent to one with skill in the art upon examination of the following figures and detailed description. It is intended that all such additional systems, methods, features and advantages be included within this description, be within the scope of the present disclosure. Further aspects and advantages are discussed below in conjunction with embodiments of the disclosure.

In this regard, each light-emitting element made of an inorganic material may be disposed in a display area (Active Area: AA).

A power signal such as a high potential voltage VDD or a low potential voltage VSS may be supplied to each light-emitting element disposed in the display area, and a data signal and a clock signal for controlling each light-emitting element may be supplied thereto.

The inventor of the present disclosure has invented a display device capable of supplying a power signal, a data signal, a clock signal, and the like to a display area in which each light-emitting element made of an inorganic material is disposed.

One technical purpose of an embodiment of the present disclosure is to provide a display device in which a plurality of light-emitting elements and a driving chip for controlling a light emission operation of the light-emitting elements are electrically connected to each other and are disposed in a display area, power signals from a pad disposed in a non-display area are directly applied to the driving chip of the display area, and data and a clock signal from the pad are applied to each of block areas of the display area.

Purposes according to the present disclosure are not limited to the above-mentioned purpose. Other purposes and advantages according to the present disclosure that are not mentioned may be understood based on following descriptions and may be more clearly understood based on embodiments according to the present disclosure. Further, it will be easily understood that the purposes and advantages according to the present disclosure may be realized using means shown in the claims or combinations thereof.

A display device according to embodiments of the present disclosure may include: a substrate including a display area and a non-display area; a plurality of driving chips disposed on the display area of the substrate; a plurality of light-emitting elements disposed on the display area and electrically connected to the driving chip; and a pad disposed on the non-display area and including a pad electrode electrically connected to the plurality of light-emitting elements, wherein the display area extends in row and column directions, wherein the display area is divided into a plurality of block areas disposed in each of both opposing sides around a central column virtual line of the display area, wherein both block areas are arranged in the row direction in a symmetrical manner to each other around the central column virtual line, wherein the plurality of block areas are arranged in the column direction, wherein power signals from the pad are directly applied to the plurality of driving chips, wherein a data signal and a clock signal from the pad are applied to the plurality of driving chips of each of the block areas.

A display device according to embodiments of the present disclosure may include: a substrate including a display area and a non-display area; a plurality of driving chips disposed on the display area of the substrate; a plurality of light-emitting elements disposed on the display area and on top of the driving chip, and electrically connected to the driving chip; a pad disposed on the non-display area and including a pad electrode electrically connected to the plurality of light-emitting elements; an optical insulating layer disposed on the display area of the substrate so as to surround each of the plurality of light-emitting elements, wherein the optical insulating layer are further disposed on top of the plurality of light-emitting elements; and a black matrix disposed on the optical insulating layer and having a plurality of openings defined therein respectively at positions corresponding to the plurality of light-emitting elements, wherein the display area extends in row and column directions, wherein the display area is divided into a plurality of block areas disposed in each of both opposing sides around a central column virtual line of the display area, wherein both block areas are arranged in the row direction in a symmetrical manner to each other around the central column virtual line, wherein the plurality of block areas are arranged in the column direction, wherein power signals from the pad are directly applied to the plurality of driving chips, wherein a data signal and a clock signal from the pad are applied to the plurality of driving chips of each of the block areas.

According to an embodiment of the present disclosure, the power signals may be directly applied to the driving chip disposed on the display area from the pad of the non-display area, and the data signal and the clock signal may be applied to the driving chips in each of the block areas of the display area

According to an embodiment of the present disclosure, the power signals may be applied to the driving chip of the display area via a dual metal line composed of two metal lines respectively disposed on the different insulating layers.

According to an embodiment of the present disclosure, the power signals, the data signal, and the clock signal may be applied to the driving chip of the display area via a plurality of metal lines respectively disposed on the different insulating layers.

According to an embodiment of the present disclosure, the plurality of metal lines respectively disposed on the different insulating layers may be positioned to vertically overlap the plurality of openings corresponding to the plurality of light-emitting elements, thereby preventing or reducing light incident through the openings from being transmitted to the driving chip.

According to an embodiment of the present disclosure, the data signal and the clock signals may be prevented from being applied to the driving chip of the display area in a delayed manner.

According to an embodiment of the present disclosure, the data signal and the clock signal are applied to the driving chips of each of the block areas of the display area, thereby preventing or reducing the delay in the application time thereof.

According to an embodiment of the present disclosure, the power signals may be applied to the driving chip of the display area via a dual metal line composed of two metal lines respectively disposed on the different insulating layers, thereby preventing the metal lines from being short-circuited with each other, and reducing the resistance of each of the metal lines.

According to an embodiment of the present disclosure, the power consumption for light emission may be reduced as the power signal, the data signal, and the clock signal are reliably applied to the driving chip of a display area.

According to an embodiment of the present disclosure, as the power consumption of the light-emitting element is reduced, a decrease in lifespan of the display device may be prevented or reduced.

According to an embodiment of the present disclosure, the power consumption of the light-emitting element is reduced, and a decrease in the lifespan of the display device is prevented or reduced, thereby providing a long-lifespan and low power display device.

According to an embodiment of the present disclosure, as the power signal, the data signal, and the clock signal are reliably applied to the driving chip of the display area, a defect of a product may be reduced, the lifespan of the display panel may be improved, and the quality of the display device may be improved.

In addition, according to an embodiment of the present disclosure, as the power signal, the data signal, and the clock signal are reliably applied to the driving chip for controlling the light-emitting elements, thereby improving the product quality and securing the product reliability.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exploded perspective view of a display device according to an embodiment of the present disclosure.

FIG. 2 is a plan view of a display device according to an embodiment of the present disclosure.

FIG. 3 is an enlarged view of a display device according to an embodiment of the present disclosure.

FIG. 4 is a diagram illustrating a circuit structure according to an embodiment of the present disclosure.

FIG. 5 is a plan view of a display device according to an embodiment of the present disclosure.

FIG. 6 is a plan view of a display device according to an embodiment of the present disclosure.

FIG. 7 is a plan view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIGS. 10 to 13 are diagrams illustrating an apparatus to which a display device according to embodiments of the present disclosure is applied.

FIG. 14 is a plan view illustrating an area in which one pixel driving circuit among a plurality of pixel driving circuits is disposed according to embodiments of the present disclosure.

FIG. 15 is a plan view schematically illustrating a configuration of a display device according to an embodiment of the present disclosure.

FIG. 16 is a plan view illustrating an example in which a power line is disposed in a display device according to an embodiment of the present disclosure.

FIG. 17 is a plan view illustrating an example in which another power line is disposed in a display device according to an embodiment of the present disclosure.

FIG. 18 is a plan view illustrating an example in which a display area is divided into a plurality of block areas according to an embodiment of the present disclosure.

FIG. 19 is a diagram illustrating an example of a structure in which a clock signal is applied to a left block area of a display area according to an embodiment of the present disclosure.

FIG. 20 is a diagram illustrating an example of a structure in which a clock signal is applied to a right block area of a display area according to an embodiment of the present disclosure.

FIGS. 21A-21C are cross-sectional views illustrating an example in which a metal line of each of layers is disposed to overlap each opening in a display device according to an embodiment of the present disclosure.

FIG. 22 is a plan view of a display device according to another embodiment of the present disclosure.

FIG. 23 is a diagram illustrating a touch operation of a display device according to another embodiment of the present disclosure.

FIG. 24 illustrates an example of a signal waveform diagram when a display device according to an embodiment of the present disclosure operates.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the technical idea and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in the present disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the technical idea and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” etc. should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Description.

In description of flow of a signal, for example, when a signal is delivered from a node A to a node B, this may include a case where the signal is transferred from the node A to the node B via another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction intersect each other at an angle other than 90 degrees or the X-axis direction, the Y-axis direction, and the Z-axis direction intersect each other at an angle other than 90 degrees within a range in which a configuration of the present disclosure may work functionally.

When a first component or layer is described as “contacting” or “overlapping” a second component or layer, it should be understood that the first component or layer may directly contact or overlap the second component or layer, or a third component or layer may be interposed between the first and second components or layers that may indirectly contact or overlap each other unless otherwise specified.

Hereinafter, various embodiments of the present disclosure will be described in detail with reference to the accompanying drawings.

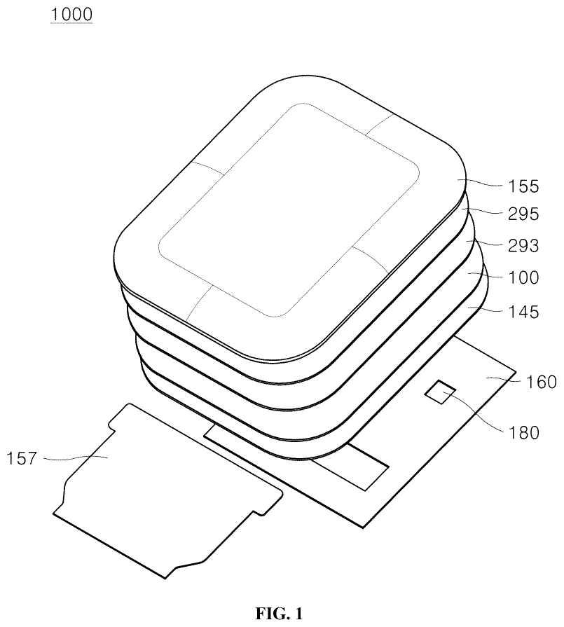

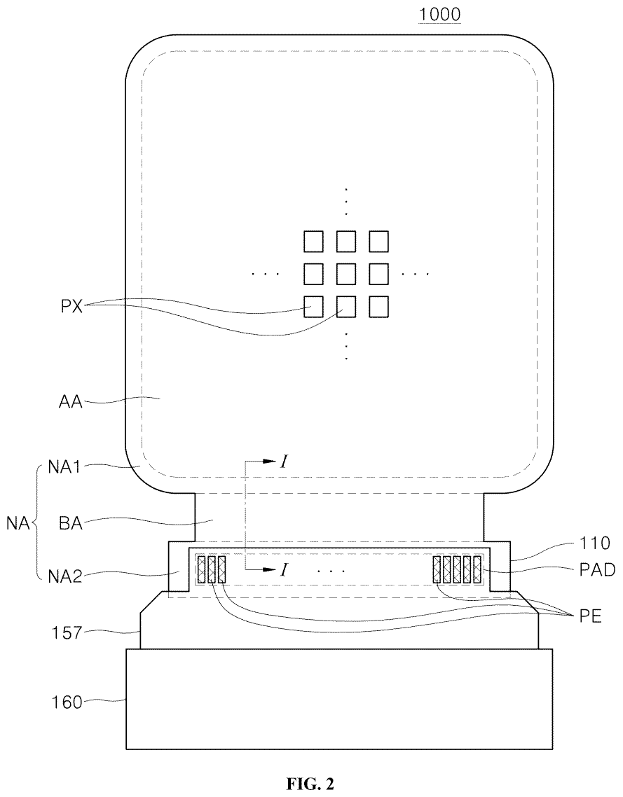

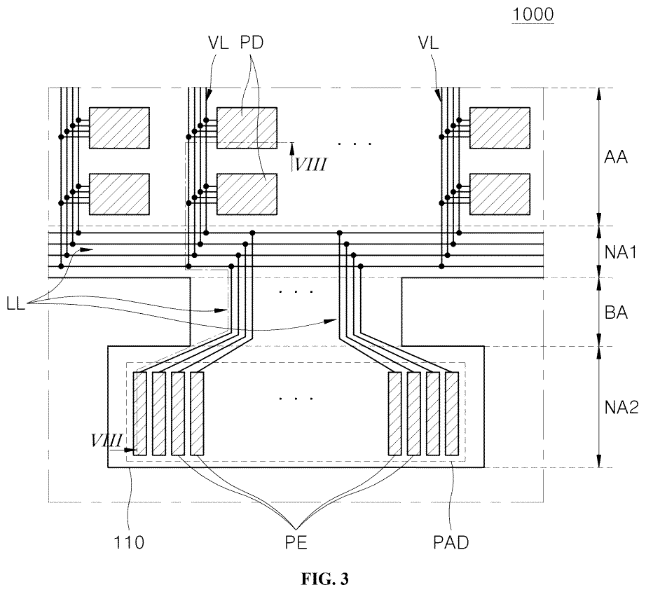

FIG. 1 is an exploded perspective view of a display device according to an embodiment of the present disclosure. FIG. 2 is a plan view of a display device according to an embodiment of the present disclosure. FIG. 3 is an enlarged view of a display device according to an embodiment of the present disclosure.

Referring to FIGS. 1 to 3, a display device 1000 according to an embodiment of the present disclosure may include a display panel 100, a polarizing layer 293, an adhesive layer 295, a cover member 155, a support substrate 145, a flexible circuit board 157, and a printed circuit board 160.

For example, the display device 1000 may include a substrate 110. The substrate 110 may be a member supporting other components of the display device 1000. The substrate 110 may be made of an insulating material. For example, the substrate 110 may be made of glass or resin. In addition, the substrate 110 may be made of a material having flexibility. For example, the substrate 110 may be made of a plastic material having flexibility, such as polyimide (PI). However, embodiments of the present disclosure are not limited thereto.

The display panel 100 may implement information, a video, and/or an image to be provided to a user. For example, the display panel 100 may include a display area AA and a non-display area NA. For example, the substrate 110 may include the display area AA and the non-display area NA. The distinction between the display area AA and the non-display area NA is applied not only to the substrate 110 but also to the display device 1000.

The display area AA may be an area in which an image is displayed. The display area AA may include a plurality of pixels PX. Each of the plurality of pixels PX may be composed of a plurality of sub-pixels. A plurality of light-emitting elements may be disposed in each of the plurality of sub-pixels SP. A type of each of the plurality of light-emitting elements may vary according to a type of the display device 1000. For example, when the display device 1000 is an inorganic light-emitting display device, the light-emitting element may be a light-emitting diode (LED), a micro light-emitting diode (LED), or a mini light-emitting diode (LED). However, embodiments of the present disclosure are not limited thereto.

The non-display area NA may be an area in which no image is displayed. Various lines and circuits for driving the plurality of pixels PX of the display area AA may be disposed in the non-display area NA. For example, various wires and driving circuits may be mounted in the non-display area NA, and a pad PAD to which an integrated circuit, a printed circuit, etc. are connected may be disposed in the non-display area NA. However, embodiments of the present disclosure are not limited thereto.

For example, the driving circuit may be a data driving circuit and/or a gate driving circuit. However, embodiments of the present disclosure are not limited thereto. Wires to which a control signal for controlling the driving circuits is supplied may be disposed. For example, the control signal may include various timing signals including a clock signal, an input data enable signal, and synchronization signals. However, embodiments of the present disclosure are not limited thereto. The control signal may be received via the pad PAD. For example, link lines LL for transmitting signals may be disposed in the non-display area NA. For example, driving components such as a flexible printed circuit board 157 and a printed circuit board 160 may be connected to the pad PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA is an area extending from at least one of a plurality of sides of the first non-display area NA1 and may be a bendable area. The second non-display area NA2 may be an area extending from the bending area BA, and the pad PAD may be disposed in the second non-display area. For example, the bending area BA may be in a bent state, and the remaining area of the substrate 110 except for the bending area BA may be in a flat state. In this case, as the bending area BA is bent, the second non-display area NA2 may be located on a rear surface of the display area AA. However, embodiments of the present disclosure are not limited thereto.

The display area AA of the substrate 110 or the display device 1000 may be formed in various shapes according to the designs of the display device 1000. For example, the display area AA may be formed in a rectangular shape having four corners of a round shape. However, embodiments of the present disclosure are not limited thereto. In another example, the display area AA may be formed in a rectangular shape in which four corners have a right angle or a circular shape. However, embodiments of the present disclosure are not limited thereto.

According to the present disclosure, a width of the second non-display area NA2 in which a plurality of pad electrodes PE are disposed may be greater than a width of the bending area BA in which only a plurality of link lines LL are disposed. In addition, the width of the display area AA in which the plurality of sub-pixels are disposed may be greater than the width of the bending area BA in which the plurality of link lines LL are disposed. Although the width of the bending area BA is illustrated as being smaller than the width of the remaining area of the substrate 110 in the drawing, a shape of the substrate 110 including the bending area BA is merely an example, and embodiments of the present disclosure are not limited thereto.

Referring to FIG. 3, a plurality of pixel driving circuits PD may be disposed in the display area AA. The plurality of pixel driving circuits PD may be circuits for driving the light-emitting elements of the plurality of sub-pixels. For example, each of the plurality of pixel driving circuits PD may perform a function of a driving transistor, and a function of a storage capacitor, etc. For example, each of the plurality of pixel driving circuits PD may control an emission operation of the plurality of light-emitting elements by supplying a control signal, a power, and a driving current to the light-emitting elements of the plurality of sub-pixels. For example, the pixel driving circuit PD may include a power line and a signal line for controlling the emission on/off and/or emission time of the light-emitting element. For example, each of the plurality of pixel driving circuits PD may be a driver manufactured using a metal-oxide-silicon field effect transistor (MOSFET) manufacturing process and disposed on a semiconductor substrate. However, embodiments of the present disclosure are not limited thereto. The driver may drive the plurality of sub-pixels. For example, each of the plurality of pixel driving circuits PD may include a micro driver (Driver). However, embodiments of the present disclosure are not limited thereto. The micro driver may be implemented in a form of a chip. For example, each of the plurality of pixel driving circuits PD may include a driving chip. However, embodiments of the present disclosure are not limited thereto.

Referring to FIG. 1 and FIG. 2, the flexible circuit board 157 and the printed circuit board 160 may be disposed under the display panel 100. The flexible circuit board 157 and the printed circuit board 160 may be disposed at least at one edge of the display panel 100. However, embodiments of the present disclosure are not limited thereto. One side of the flexible circuit board 157 may be attached to the display panel 100 and the other side thereof may be attached to the printed circuit board 160. However, embodiments of the present disclosure are not limited thereto. The flexible circuit board 157 may be a flexible film. However, embodiments of the present disclosure are not limited thereto.

The pad PAD including a plurality of pad electrodes PE may be disposed in the second non-display area NA2. A driving component including one or more flexible circuit boards (or flexible films) 157 and the printed circuit board 160 may be attached or bonded to the pad PAD. The plurality of pad electrodes PE of the pad PAD may be electrically connected to one or more flexible circuit boards (or flexible films) 157 and may transmit various signals (or power) from the printed circuit board 160 and the flexible circuit boards (or flexible films) 157 to the plurality of pixel driving circuits PD of the display area AA.

The flexible circuit board (or flexible film) 157 may be a film in which various components are disposed on a flexible base film. For example, a driving IC such as a gate driver IC or a data driver IC may be disposed on the flexible circuit board (or flexible film) 157. However, embodiments of the present disclosure are not limited thereto. The driving IC may be a component that processes data for displaying an image and a driving signal. The driving IC may be disposed in a manner such as a Chip On Glass (COG), a Chip On Film (COF), or a Tape Carrier Package (TCP) according to a mounted manner. However, embodiments of the present disclosure are not limited thereto. The flexible circuit board (or flexible film) 157 may be attached or bonded to the plurality of pad electrodes PE via a conductive adhesive layer. However, embodiments of the present disclosure are not limited thereto.

The printed circuit board 160 may be electrically connected to one or more flexible circuit boards (or flexible films) 157 and may be a component that supplies a signal to the driving IC. The printed circuit board 160 may be disposed on one side of the flexible circuit board (or flexible film) 157 so as to be electrically connected to the flexible circuit board (or flexible film) 157. Various components for supplying various signals to the driving IC may be disposed on the printed circuit board 160. For example, various components such as a timing controller, a power supply unit, a memory, or a processor may be disposed on the printed circuit board 160. For example, the printed circuit board 160 may include a power management integrated circuit (PMIC). However, embodiments of the present disclosure are not limited thereto.

The printed circuit board 160 may include at least one hole 180. However, embodiments of the present disclosure are not limited thereto. An internal component for sensing ambient light or temperature that may be provided to the plurality of sensors may be disposed in an area corresponding to the at least one hole 180. For example, the internal component may include an ALS (Ambient light sensor), a temperature sensor, etc. However, embodiments of the present disclosure are not limited thereto. For example, the hole 180 may be a transmission hole or the like. However, embodiments of the present disclosure are not limited thereto.

Referring to FIG. 1, the polarizing layer 293 may be disposed on the display panel 100. The polarizing layer 293 may prevent or reduce light generated from an external light source from entering the display panel 100 and thus affecting the light-emitting element or the like.

The cover member 155 may be disposed on the polarizing layer 293. The cover member 155 may be a member for protecting the display panel 100. The adhesive layer 295 may be disposed between the polarizing layer 293 and the cover member 155. The cover member 155 may be attached to the display panel 100 via the adhesive layer 295. The adhesive layer 295 may include an OCA (optically clear adhesive), an OCR (optically clear resin), a PSA (pressure sensitive adhesive), etc. However, embodiments of the present disclosure are not limited thereto.

The support substrate 145 may be disposed between the display panel 100 and the printed circuit board 160. The support substrate 145 may reinforce the rigidity of the display panel 100. The support substrate 145 may be a back plate. However, embodiments of the present disclosure are not limited thereto.

Referring to FIGS. 1 to 3, the plurality of link lines LL may be disposed in the non-display area NA. The plurality of link lines LL may be lines for transmitting various signals from one or more flexible circuit boards (or flexible films) 157 and the printed circuit board 160 to the display area AA. The plurality of link lines LL may extend from the plurality of pad electrodes PE of the second non-display area NA2 toward the bending area BA and the first non-display area NA1 and may be electrically connected to the plurality of driving lines VL of the display area AA. The plurality of pixel driving circuits PD may be driven upon receiving signals from one or more flexible circuit boards (or flexible films) 157 and the printed circuit boards 160 via driving lines VL of the display area AA and the link lines LL of the non-display area NA.

For example, a plurality of driving lines VL together with the plurality of link lines LL may transmit signals output from the flexible circuit board (or flexible film) 157 and the printed circuit board 160 to the plurality of pixel driving circuits PD. The plurality of driving lines VL may be disposed in the display area AA and may be electrically connected to each of the plurality of pixel driving circuits PD. The plurality of driving lines VL may extend from the display area AA toward the non-display area NA and may be electrically connected to the plurality of link lines LL.

As the bending area BA is bent, a portion of each of the plurality of link lines LL may also be bent. Thus, stress is concentrated on a portion of the bent link line LL, and accordingly, a crack may occur in the link line LL. Accordingly, the plurality of link lines LL may be made of a conductive material having excellent ductility to reduce the cracks occurring when the bending area BA is bent. For example, the plurality of link lines LL may be made of a conductive material having excellent ductility, such as gold (Au), silver (Ag), aluminum (Al), etc. However, embodiments of the present disclosure are not limited thereto. In addition, the plurality of link lines LL may be made of one of various conductive materials used in the display area AA. For example, the plurality of link lines LL may be made of molybdenum (Mo), chromium (Cr), titanium (Ti), nickel (Ni), neodymium (Nd), copper (Cu), an alloy thereof, or an alloy of silver (Ag) and magnesium (Mg). However, embodiments of the present disclosure are not limited thereto. The plurality of link lines LL may be configured in a multilayer structure including various conductive materials. For example, the plurality of link lines LL may be configured in a triple layer structure of a titanium (Ti) layer/aluminum (Al) layer/titanium (Ti) layer. However, embodiments of the present disclosure are not limited thereto.

The plurality of link lines LL may be formed in various shapes to reduce the stress. At least a portion of each of the plurality of link lines LL disposed on the bending area BA may extend in the same direction as an extending direction of the bending area BA or may extend in a direction different from the extending direction of the bending area BA to reduce the stress. For example, when the bending area BA extends in one direction from the first non-display area NA1 toward the second non-display area NA2, at least a portion of the link line LL disposed on the bending area BA may extend in a direction inclined with respect to the one direction. In another example, at least a portion of each of the plurality of link lines LL may be formed in each of patterns of various shapes. For example, at least a portion of each of the plurality of link lines LL disposed on the bending area BA may have a shape in which conductive patterns having at least one of a diamond shape, a rhombus shape, a trapezoidal shape, a triangular wave shape, a sawtooth wave shape, a sine wave shape, a circular shape, and an omega (Q) shape are repeatedly arranged. However, embodiments of the present disclosure are not limited thereto.

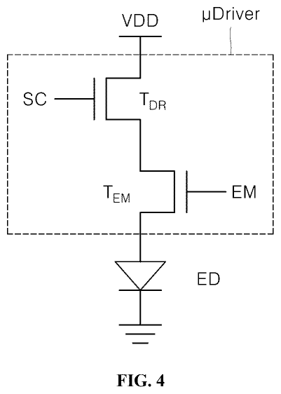

FIG. 4 is a diagram illustrating a circuit structure according to an embodiment of the present disclosure.

FIG. 4 illustrates that one light-emitting element ED is connected to one micro driver Driver. However, embodiments of the present disclosure are not limited thereto. For example, eight light-emitting elements ED may be simultaneously connected to one micro driver μDriver. In another example, 16 light-emitting elements ED may simultaneously be connected to one micro driver μDriver, or 32 light-emitting elements ED or 64 light-emitting elements ED may be simultaneously connected to one micro driver μDriver or 64 light-emitting elements ED or 256 light-emitting elements ED may be simultaneously connected to one micro driver μDriver or 768 light-emitting elements ED may be simultaneously connected to one micro driver μDriver. The light-emitting element ED may be a micro light-emitting element LED. In another example, one micro driver μDriver may control a plurality of pixels arranged in a matrix (16×16) manner in the column direction and the row direction of the substrate. Each of the plurality of pixels may include a plurality of light-emitting elements ED.

One micro driver μDriver may be implemented in a form of a chip. For example, the micro driver μDriver implemented in the form of the chip may include a driving transistor TDR and a light-emission transistor TEM. However, embodiments of the present disclosure are not limited thereto.

For example, in the micro driver μDriver, a high potential power voltage VDD may be applied to a first electrode of the driving transistor TDR, a first electrode of the light-emission transistor TEM may be connected to a second electrode of the driving transistor TDR, and a scan signal SC may be applied to a gate electrode of the driving transistor TDR. The scan signal SC applied to the gate electrode of the driving transistor TDR is a direct current power, and a fixed reference voltage Vref may be applied thereto every frame. However, embodiments of the present disclosure are not limited thereto.

The second electrode of the driving transistor TDR may be connected to the first electrode of the light-emission transistor TEM, the light-emitting element ED may be connected to a second electrode of the light-emission transistor TEM, and the light-emission signal EM may be applied to a gate electrode of the light-emission transistor TEM. The light-emission signal EM applied to the gate electrode of the light-emission transistor TEM may be a pulse width modulation signal that varies in every frame. However, embodiments of the present disclosure are not limited thereto.

The light-emitting element ED may have a first electrode connected to the second electrode of the light-emission transistor TEM, and a second electrode connected to the ground. For example, the first electrode thereof may be an anode electrode, and the second electrode thereof may be a cathode electrode. However, embodiments of the present disclosure are not limited thereto.

Each of the driving transistor TDR and the light-emission transistor TEM may be an n-type transistor or a p-type transistor.

In the micro driver μDriver, the driving transistor TDR may be turned on based on the scan signal SC applied thereto from a timing controller T-CON, and the light-emission transistor TEM may be turned on based on the light-emission signal EM. Accordingly, the driving current is applied to the light-emitting element ED via the driving transistor TDR and the light-emission transistor TEM based on the high potential power voltage VDD applied to the first electrode of the driving transistor TDR, so that the light-emitting element ED may emit light.

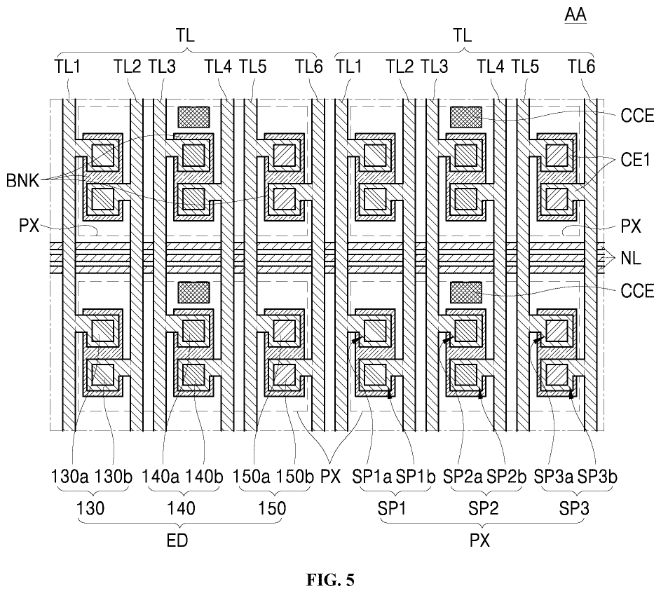

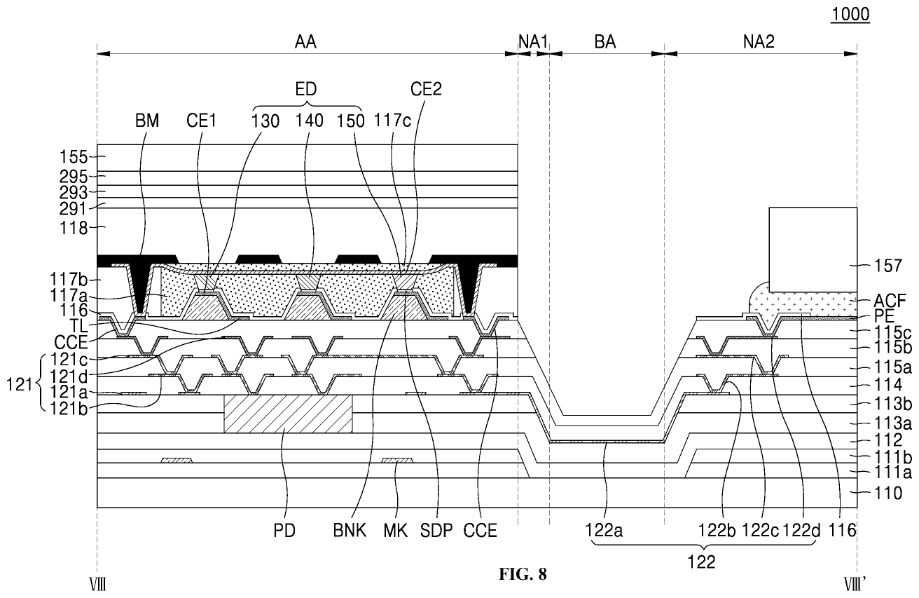

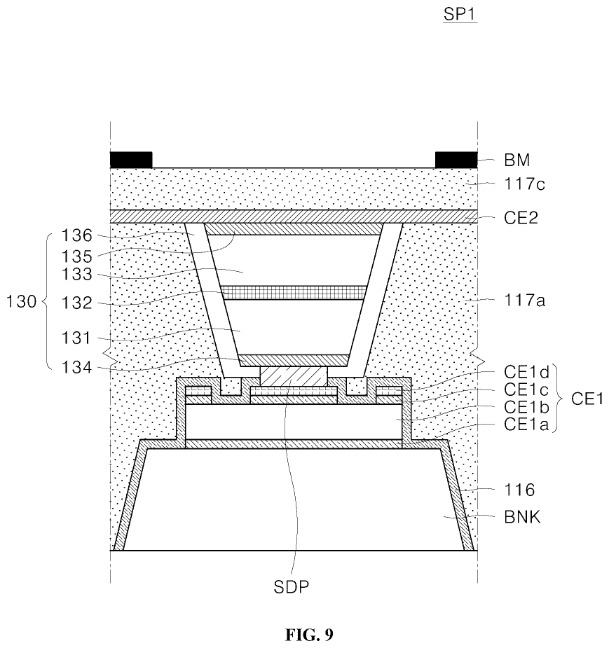

FIGS. 5 to 7 are plan views of a display device according to an embodiment of the present disclosure. FIGS. 8 and 9 are cross-sectional views of a display device according to an embodiment of the present disclosure.

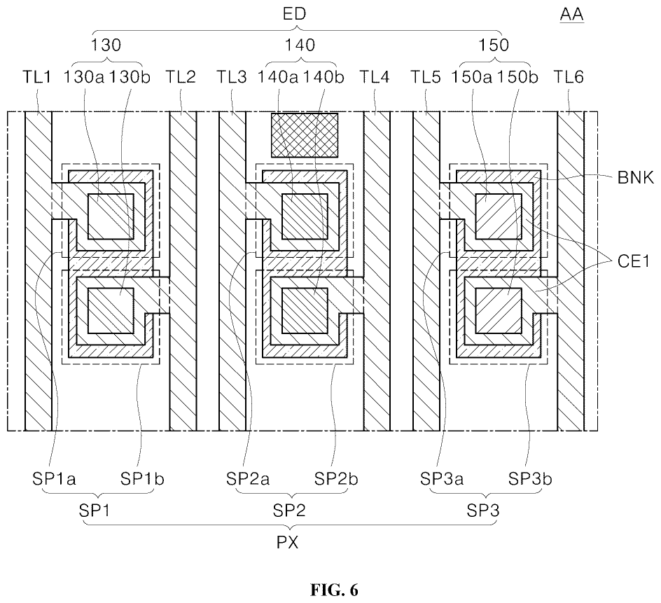

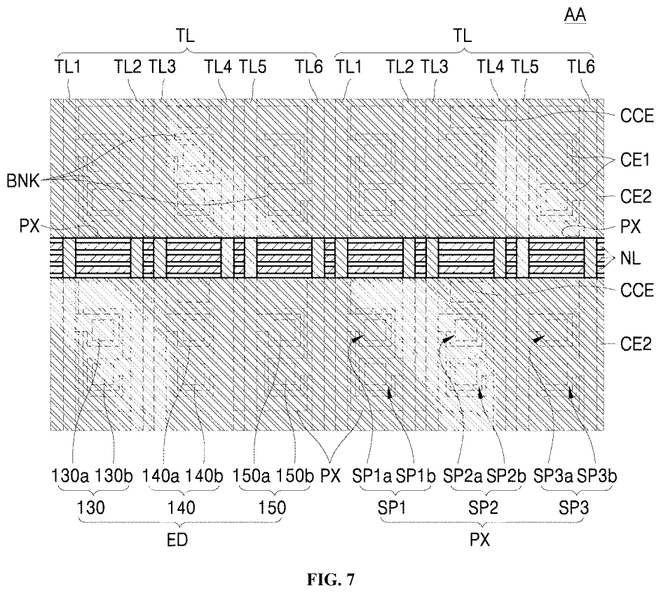

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA1, the bending area BA, and the second non-display area NA2. FIG. 8 is a cross-sectional view of the display device taken along a cutting line VIII-VIII′ of FIG. 3. For example, FIG. 9 is a cross-sectional view of a display area including one sub-pixel SPL. For convenience of illustration, FIG. 3 illustrates that the cutting line VIII-VIII′ and the driving line VL and the link line LL do not overlap each other. However, the present disclosure is not limited thereto. The cutting line VIII-VIII′ of FIG. 3 is intended for indicating that a position thereof is the same as that of each of the driving line VL and the link line LL adjacent thereto. FIGS. 5 and 6 illustrate only a plurality of signal lines TL, a plurality of communication lines NL, a plurality of first electrodes CE1, a plurality of banks BNK, and a plurality of light-emitting elements ED. However, embodiments of the present disclosure are not limited thereto. FIG. 7 is an enlarged plan view in which a plurality of second electrodes CE2 are additionally disposed in FIG. 5.

Referring to FIGS. 5, 6, and 9, a plurality of pixels PX, each including a plurality of sub-pixels, may be disposed in the display area AA. Each of the plurality of sub-pixels includes a light-emitting element ED and may independently emit light. The plurality of sub-pixels may be arranged in a plurality of rows and a plurality of columns and thus may be arranged in a matrix form. However, embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2, and the third sub-pixel SP3 may be a red sub-pixel, another thereof may be a green sub-pixel, and the other thereof may be a blue sub-pixel. A type of each of the plurality of sub-pixels is an example, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a (1-1)-th sub-pixel SP1a and a (1-2)-th sub-pixel SP1b. The pair of second sub-pixels SP2 may include a (2-1)-th sub-pixel SP2a and a (2-2)-th sub-pixel SP2b. The pair of third sub-pixels SP3 may include a (3-1)-th sub-pixel SP3a and a (3-2)-th sub-pixel SP3b. For example, one pixel PX may include a (1-1)-th sub-pixel SP1a and a (1-2)-th sub-pixel SP1b, a (2-1)-th sub-pixel SP2a and a (2-2)-th sub-pixel SP2b, and a (3-1)-th sub-pixel SP3a and a (3-2)-th sub-pixel SP3b. However, embodiments of the present disclosure are not limited thereto.

The plurality of sub-pixels constituting one pixel PX may be arranged in various manner. In one example, in one pixel PX, a pair of first sub-pixels SP1 may be arranged in the same column, a pair of second sub-pixels SP2 may be arranged in the same column, and a pair of third sub-pixels SP3 may be arranged in the same column. The first sub-pixel SP1, the second sub-pixel SP2, and the third sub-pixel SP3 may be arranged in the same row. The number and arrangement of the plurality of sub-pixels constituting one pixel PX are examples, and embodiments of the present disclosure are not limited thereto.

A plurality of signal lines TL may be disposed in an area between adjacent ones of the plurality of sub-pixels. The plurality of signal lines TL may extend in the column direction while being disposed between adjacent ones of the plurality of sub-pixels. The plurality of signal lines TL may be lines for transmitting an anode voltage from the pixel driving circuit PD to the plurality of sub-pixels. For example, the plurality of signal lines TL may be electrically connected to the plurality of pixel driving circuits PD and the first electrodes CE1 of the plurality of sub-pixels. The anode voltage output from the pixel driving circuit PD may be transmitted to the first electrodes CE1 of the plurality of sub-pixels via the plurality of signal lines TL. For example, the first electrode CE1 may be an electrode electrically connected to the anode electrode 134 of the light-emitting element ED. Accordingly, the anode voltage from the signal line TL may be transmitted to the anode electrode 134 of the light-emitting element ED via the first electrode CE.

Therefore, a structure of the display device 1000 may be simplified using the pixel driving circuit PD in which the plurality of pixel circuits are integrated with each other, instead of forming a plurality of transistors and a storage capacitor in each of the plurality of sub-pixels. In addition, as circuits respectively disposed in the plurality of sub-pixels are integrated into one pixel driving circuit PD, high-efficiency low-power operation of the display device may be achieved.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to the pair of first sub-pixels SP1, respectively. The third signal line TL3 and the fourth signal line TL4 may be electrically connected to the pair of second sub-pixels SP2, respectively. The fifth signal line TL5 and the sixth signal line TL6 may be electrically connected to the pair of third sub-pixels SP3, respectively.

The first signal line TL1 may be disposed on one side of the pair of first sub-pixels SP1, and the second signal line TL2 may be disposed on another side of the pair of first sub-pixels SP1. The first signal line TL1 may be electrically connected to one first sub-pixel SP1 of the pair of first sub-pixels SP1, for example, the first electrode CE1 of the (1-1)-th sub-pixel SP1a. The second signal line TL2 may be electrically connected to the other first sub-pixel SP1 of the pair of first sub-pixels SP1, for example, the first electrode CE1 of the (1-2)-th sub-pixel SP1b.

The third signal line TL3 may be disposed on one side of the pair of second sub-pixels SP2, and the fourth signal line TL4 may be disposed on another side of the pair of second sub-pixels SP2. For example, the third signal line TL3 may be disposed adjacent to the second signal line TL2. The third signal line TL3 may be electrically connected to one second sub-pixel SP2 of the pair of second sub-pixels SP2, for example, the first electrode CE1 of the (2-1)-th sub-pixel SP2a. The fourth signal line TL4 may be electrically connected to the other second sub-pixel SP2 of the pair of second sub-pixels SP2, for example, the first electrode CE1 of the (2-2)-th sub-pixel SP2b.

The fifth signal line TL5 may be disposed on one side of the pair of third sub-pixels SP3, and a sixth signal line TL6 may be disposed on another side of the pair of third sub-pixels SP3. For example, the fifth signal line TL5 may be disposed adjacent to the fourth signal line TL4. The sixth signal line TL6 may be disposed adjacent to the first signal line TL1 connected to the pixel PX adjacent thereto. The fifth signal line TL5 may be electrically connected to one third sub-pixel SP3 of the pair of third sub-pixels SP3, for example, the first electrode CE1 of the (3-1)-th sub-pixel SP3a. The sixth signal line TL6 may be electrically connected to the other third sub-pixel SP3 of the pair of third sub-pixels SP3, for example, the first electrode CE1 of the (3-2)-th sub-pixel SP3b.

Each of the plurality of signal lines TL may be made of a conductive material. For example, each of the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. However, embodiments of the present disclosure are not limited thereto. In another example, each of the plurality of signal lines TL may have a multilayer structure made of a conductive material. For example, each of the plurality of signal lines TL may have a multilayer structure of a titanium (Ti) layer/aluminum (Al) layer/titanium (Ti) layer/indium tin oxide (ITO) layer. However, embodiments of the present disclosure are not limited thereto.

A plurality of communication lines NL may be disposed in an area between adjacent ones of the plurality of pixels PX. The plurality of communication lines NL may extend in the row direction while being disposed in an area between adjacent ones of the plurality of pixels PX. The plurality of communication lines NL may be disposed in an area between adjacent ones of the plurality of second electrodes CE2 and may not overlap the plurality of second electrodes CE2. For example, the plurality of communication lines NL may be lines used for short-range communication such as near field communication (NFC). The plurality of communication lines NL may function as antennas. For example, the plurality of communication lines NL may be a plurality of connection lines, etc. However, embodiments of the present disclosure are not limited thereto.

According to the present disclosure, a bank BNK may be disposed in each of the plurality of sub-pixels. Each of the plurality of banks BNK may be a structure in which each of the plurality of light-emitting elements ED is seated. The plurality of banks BNK may guide positions of the plurality of light-emitting elements ED in a transfer process of transferring the plurality of light-emitting elements ED to the substrate, respectively. In the transfer process of the plurality of light-emitting elements ED thereto, the plurality of light-emitting elements ED may be transferred onto the plurality of banks BNK, respectively. The plurality of banks BNK may be bank patterns, structures, etc. However, embodiments of the present disclosure are not limited thereto.

The bank BNK of the first sub-pixel SP1, the bank BNK of the second sub-pixel SP2, and the bank BNK of the third sub-pixel SP3 may be spaced apart from each other. The bank BNK of the first sub-pixel SP1, the bank BNK of the second sub-pixel SP2, and the bank BNK of the third sub-pixel SP3 may be constructed to be isolated from each other. Accordingly, the banks BNK of the first sub-pixel SP1, the second sub-pixel SP2, and the third sub-pixel SP3 to which different types of light-emitting elements ED are transferred, respectively may be easily identified.

The bank BNK of the (1-1)-th sub-pixel SP1a and the bank BNK of the (1-2)-th sub-pixel SP1b may be connected to each other or may be spaced apart or isolated from each other. For example, the bank BNK of the (1-1)-th sub-pixel SP1a and the bank BNK of the (1-2)-th sub-pixel SP1b in which the light-emitting elements ED of the same type are disposed, respectively may be connected to each other, or may be spaced apart or isolated from each other in consideration of a design such as a transfer process requirement. In addition, the bank BNK of the (2-1)-th sub-pixel SP2a and the bank BNK of the (2-2)-th sub-pixel SP2b may be connected to each other or may be spaced apart or isolated from each other. The bank BNK of the (3-1)-th sub-pixel SP3a and the bank BNK of the (3-2)-th sub-pixel SP3b may be connected to each other or may be spaced apart or isolated from each other. Accordingly, the banks BNK of the pair of first sub-pixels SP1, the banks BNK of the pair of second sub-pixels SP2, and the banks BNK of the pair of third sub-pixels SP3 may be variously formed. Embodiments of the present disclosure are not limited thereto.

For example, each of the plurality of banks BNK may be made of an organic insulating material. Each of the plurality of banks BNK may be formed as a single layer or multiple layers made of an organic insulating material. For example, each of the plurality of banks BNK may be made of photoresist, polyimide (PI), or an acryl-based material. However, embodiments of the present disclosure are not limited thereto.

The first electrode CE1 may be disposed in each of the plurality of sub-pixels SP. The first electrode CE1 may be disposed on the bank BNK. The first electrode CE1 may be electrically connected to one signal line TL among the plurality of signal lines TL. At least a portion of the first electrode CE1 may extend outwardly of the bank BNK and may be electrically connected to the signal line TL closest to the first electrode CE1. For example, a portion of the first electrode CE1 of the (1-1)-th sub-pixel SP1a may extend to one side area of the (1-1)-th sub-pixel SP1a so as to be electrically connected to the first signal line TL1, and a portion of the first electrode CE1 of the (1-2)-th sub-pixel SP1b may extend to the other side area of the (1-2)-th sub-pixel SP1b so as to be electrically connected to the second signal line TL2. A portion of the first electrode CE1 of the (2-1)-th sub-pixel SP2a may extend to one side area of the (2-1)-th sub-pixel SP2a so as to be electrically connected to the third signal line TL3, and a portion of the first electrode CE1 of the (2-1)-th sub-pixel SP2b may extend to the other side area of the (2-1)-th sub-pixel SP2b so as to be electrically connected to the fourth signal line TL4. A portion of the first electrode CE1 of the (3-1)-th sub-pixel SP3a may extend to one side area of the (3-1)-th sub-pixel SP3a so as to be electrically connected to the fifth signal line TL5, and a portion of the first electrode CE1 of the (3-2)-th sub-pixel SP3b may extend to the other side area of the (3-2)-th sub-pixel SP3b so as to be electrically connected to the sixth signal line TL6.

The first electrode CE1 may be electrically connected to the anode electrode 134 of the light-emitting element ED and may transmit an anode voltage from the pixel driving circuit PD to the light-emitting element ED via the signal line TL. Different voltages may be respectively applied to the first electrodes CE1 of the plurality of sub-pixels based on a displayed image. For example, different voltages may be applied to the first electrodes CE1 of the plurality of sub-pixels SP, respectively. Accordingly, the first electrode CE1 may be a pixel electrode, and embodiments of the present disclosure are not limited thereto.

The first electrode CE1 may be made of a conductive material. For example, the first electrode CE1 may be integrally formed with the plurality of signal lines TL. For example, the first electrode CE1 may be made of the same conductive material as that of each of the plurality of signal lines TL. However, embodiments of the present disclosure are not limited thereto.

The light-emitting element ED may be disposed in each of the plurality of sub-pixels. The plurality of light-emitting elements ED may be one of a light-emitting diode (LED) or a micro light-emitting diode (LED). However, embodiments of the present disclosure are not limited thereto. The plurality of light-emitting elements ED may be disposed on the bank BNK and the first electrode CE1. The plurality of light-emitting elements ED may be disposed on the first electrode CE1 and may be electrically connected to the first electrode CE1. Accordingly, the light-emitting element ED may receive the anode voltage from the pixel driving circuit PD via the signal line TL and the first electrode CE1 to emit light.

The plurality of light-emitting elements ED may include a first light-emitting element 130, a second light-emitting element 140, and a third light-emitting element 150. The plurality of light-emitting elements ED may include, for example, the first light-emitting element 130 for red light emission, the second light-emitting element 140 for green light emission, and the third light-emitting element 150 for blue light emission. The first light-emitting element 130 may have a size larger than a size of each of the second light-emitting element 140 and the third light-emitting element 150.

The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another thereof may be a green light-emitting element, and the other thereof may be a blue light-emitting element. However, embodiments of the present disclosure are not limited thereto. Accordingly, various colors of light including white may be implemented by combining red light, green light, and blue light respectively emitted from the plurality of light-emitting elements ED from each other. The type of each of the plurality of light-emitting elements ED is merely an example, and embodiments of the present disclosure are not limited thereto.

The first light-emitting element 130 may include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 may include a (2-1)-th light-emitting element 140a disposed in the (2-1)-th sub-pixel SP2a and a (2-1)-th light-emitting element 140b disposed in the (2-1)-th sub-pixel SP2b. The third light-emitting element 150 may include a (3-1)-th light-emitting element 150a disposed in the (3-1)-th sub-pixel SP3a and a (3-2)-th light-emitting element 150b disposed in the (3-2)-th sub-pixel SP3b.

Referring to FIGS. 5 and 6, and FIGS. 7 and 9 together, the second electrode CE2 may be disposed in each of the plurality of sub-pixels SP. The second electrode CE2 may be disposed on the light-emitting element ED. The second electrode CE2 may be electrically connected to the pixel driving circuit PD via a plurality of contact electrodes CCE.

For example, the second electrode CE2 may be electrically connected to the cathode electrode 135 of the light-emitting element ED to transmit the cathode voltage from the pixel driving circuit PD to the light-emitting element ED. The same cathode voltage may be applied to the second electrodes CE2 of the plurality of sub-pixels SP. For example, the same voltage may be applied to the second electrodes CE2 of the plurality of sub-pixels and the cathode electrode 135 of the light-emitting element ED. Accordingly, the second electrode CE2 may be a common electrode. However, embodiments of the present disclosure are not limited thereto.

At least some of the plurality of sub-pixels may share the second electrode CE2 with each other. At least some of the second electrodes CE2 of the plurality of sub-pixels SP may be electrically connected to each other. As the same voltage is applied to the second electrodes CE2, the second electrode CE2 may be shared by the at least some sub-pixels. For example, the second electrodes CE2 of at least some pixels PX among the plurality of pixels PX disposed in the same row may be connected to each other. For example, one second electrode CE2 may be disposed in the plurality of pixels PX. One second electrode CE2 may be disposed in a combination of n sub-pixels.

For example, some of the respective second electrodes CE2 of the plurality of sub-pixels SP may be spaced apart or isolated from each other. For example, the second electrode CE2 connected to the pixels PX of an n-th row and the second electrode CE2 connected to the pixels PX of an (n+1)-th row may be spaced apart or isolated from each other. For example, adjacent ones of the plurality of second electrodes CE2 may be arranged to be spaced apart from each other while the plurality of communication lines NL extending in the row direction are disposed therebetween. Accordingly, the number of the plurality of sub-pixels may be greater than the number of the plurality of second electrodes CE2. In another example, all of the second electrodes CE2 of the plurality of sub-pixels may be connected to each other, such that only one second electrode CE2 may be disposed on the substrate 110. However, embodiments of the present disclosure are not limited thereto.

Each of the plurality of second electrodes CE2 may be made of a transparent conductive material. However, embodiments of the present disclosure are not limited thereto. Each of the plurality of second electrodes CE2 may be made of a transparent conductive material and may allow light emitted from the light-emitting element ED to be directed upwardly of the second electrode CE2. For example, the second electrode CE2 may be made of a transparent conductive material such as Indium Tin Oxide (ITO), Indium Zinc Oxide (IZO), Indium Gallium Zinc Oxide (IGZO), etc. However, embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, each of the plurality of contact electrodes CCE may be electrically connected to each of the plurality of second electrodes CE2. Each of the plurality of contact electrodes CCE may be disposed between the substrate 110 and each of the plurality of second electrodes CE2 to transmit the cathode voltage from the pixel driving circuit PD to each of the second electrodes CE2.

For example, when the micro LED is used as the light-emitting element ED, a plurality of micro LEDs may be formed on a wafer, and the micro LEDs may be transferred to the substrate 110 of the display device 1000 to manufacture the display device 1000. Various defects may occur in the process of transferring the plurality of light-emitting elements ED having a fine size from the wafer to the substrate 110. For example, a non-transfer defect in which the light-emitting element ED is not transferred may occur in some sub-pixels, and an incorrect position defect in which the light-emitting element ED is transferred out of the correct position due to an alignment error may occur in some further sub-pixels. In addition, the transfer process is normally performed, while the transferred light-emitting element ED itself may be defective. Therefore, the plurality of light-emitting elements ED of the same type may be transferred to one sub-pixel in consideration of the defect in the transfer process of the plurality of light-emitting elements ED. The lighting test of the plurality of light-emitting elements ED is performed, and only one light-emitting element ED that has been finally determined to be normal or non-defective may be used.

For example, both the (1-1)-th light-emitting element 130a and the (1-2)-th light-emitting element 130b may be transferred to one pixel PX at the same time, and whether they are defective may be inspected. When both the (1-1)-th light-emitting element 130a and the (1-2)-th light-emitting element 130b are determined to be normal or non-defective, only the (1-1)-th light-emitting element 130a may be used, and the (1-2)-th light-emitting element 130b may not be used. In another example, when only the (1-2)-th light-emitting element 130b among the (1-1)-th light-emitting element 130a and the (1-2)-th light-emitting element 130b is determined to be normal or non-defective, the (1-1)-th light-emitting element 130a may not be used and only the (1-2)-th light-emitting element 130b may be used. Therefore, even when the plurality of light-emitting elements ED of the same type are transferred to one pixel PX, only one light-emitting element ED may be finally used.

Accordingly, one of the pair of light-emitting elements ED may act as a main (primary) light-emitting element ED, and the other of the pair of light-emitting elements ED may act as a redundant light-emitting element ED. The redundant light-emitting element ED may be an extra light-emitting element ED that is transferred in preparation for the defect of the main light-emitting element ED. When the main light-emitting element ED is defective, the main light-emitting element ED may be replaced with the redundant light-emitting element ED. Accordingly, both the main light-emitting element ED and the redundant light-emitting element ED are transferred to one pixel PX at the same time, thereby minimizing a decrease in display quality due to the defect of the main light-emitting element ED and the redundant light-emitting element ED.

For example, each of the (1-1)-th light-emitting element 130a, the (2-1)-th light-emitting element 140a, and the (3-1)-th light-emitting element 150a transferred to one pixel PX may be used as the main light-emitting element ED, while each of the (1-2)-th light-emitting element 130b, the (2-2)-th light-emitting element 140b, and the (3-2)-th light-emitting element 150b may be used as the redundant light-emitting element ED.

FIG. 8 is a cross-sectional view of a display device according to an embodiment of the present disclosure. FIG. 9 is a cross-sectional view of a display device according to an embodiment of the present disclosure. For example, FIG. 8 is a cross-sectional view of the display area AA, the first non-display area NA1, the bending area BA, and the second non-display area NA2. FIG. 8 is a cross-sectional view of the display device taken along the cutting line VIII-VIII′ of FIG. 3. For example, FIG. 9 is a cross-sectional view of a display area including one sub-pixel SP1. For convenience of illustration, FIG. 3 illustrates that the cutting line VIII-VIII′ and the driving line VL and the link line LL do not overlap each other. However, the present disclosure is not limited thereto. The cutting line VIII-VIII′ of FIG. 3 is intended for indicating that a position thereof is the same as that of each of the driving line VL and the link line LL adjacent thereto.

Referring to FIG. 8, a first buffer layer 111a and a second buffer layer 111b may be disposed on the remaining area of the substrate 110 except for the bending area BA.

The first buffer layer 111a and the second buffer layer 111b may be disposed in the display area AA, the first non-display area NA1, and the second non-display area NA2. The first buffer layer 111a and the second buffer layer 111b may reduce invasion of moisture or impurities through the substrate 110. Each of the first buffer layer 111a and the second buffer layer 111b may be made of an inorganic insulating material. For example, each of the first buffer layer 111a and the second buffer layer 111b may be formed as a single layer or multiple layers made of silicon oxide (SiOx) or silicon nitride (SiNx). However, embodiments of the present disclosure are not limited thereto.

For example, a portion of each of the first buffer layer 111a and the second buffer layer 111b in the bending area BA may be removed. An upper surface of a portion of the substrate 110 located in the bending area BA may be not covered with the first buffer layer 111a and the second buffer layer 111b so as to be exposed. Removing the portion of each of the first buffer layer 111a and the second buffer layer 111b made of the inorganic insulating material as disposed in the bending area BA may allow cracks of the first buffer layer 111a and the second buffer layer 111b that may occur during bending to be minimized or at least reduced.

A plurality of alignment keys MK may be disposed between the first buffer layer 111a and the second buffer layer 111b. The plurality of alignment keys MK may be configured to identify the position of the pixel driving circuit PD during the manufacturing process of the display device 1000. For example, the plurality of alignment keys MK may be configured to correctly align the positions of the pixel driving circuits PD transferred onto the adhesive layer 112. In another example, the plurality of alignment keys MK may be omitted.

The adhesive layer 112 may be disposed on the second buffer layer 111b. The adhesive layer 112 may be disposed in the display area AA, the first non-display area NA1, the bending area BA, and the second non-display area NA2. In another example, at least a portion of the adhesive layer 112 may be removed in the non-display area NA including the bending area BA. For example, the adhesive layer 112 may be made of one of an adhesive polymer, an epoxy resin, an ultra violet (UV) curable resin, a polyimide-based resin, an acrylate-based resin, a urethane-based resin, and polydimethylsiloxane (PDMS). However, embodiments of the present disclosure are not limited thereto.

The pixel driving circuit PD may be disposed on the adhesive layer 112 and in the display area AA. When the pixel driving circuit PD is implemented as a driver, the driver may be mounted on the adhesive layer 112 in a transfer process. However, embodiments of the present disclosure are not limited thereto.

A first protective layer 113a and a second protective layer 113b may be disposed on the adhesive layer 112 and the pixel driving circuit PD. The first protective layer 113a and the second protective layer 113b may be disposed to surround a side surface of the pixel driving circuit PD. However, embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed on the bending area BA may be omitted. For example, the first protective layer 113a may be entirely disposed in the display area AA and the non-display area NA, and the second protective layer 113b may be partially disposed in the display area AA, the first non-display area NA1, and the second non-display area NA2. For example, a portion of the second protective layer 113b in the bending area BA may be removed. However, embodiments of the present disclosure are not limited thereto.

Each of the first protective layer 113a and the second protective layer 113b may be made of an organic insulating material. However, embodiments of the present disclosure are not limited thereto. For example, each of the first protective layer 113a and the second protective layer 113b may be made of a photoresist, polyimide (PI), or a photo acryl-based material. However, embodiments of the present disclosure are not limited thereto. For example, each of the first protective layer 113a and the second protective layer 113b may be embodied as an overcoat layer or an insulating layer. However, embodiments of the present disclosure are not limited thereto.

According to the present disclosure, a plurality of first connection lines 121 may be disposed on the second protective layer 113b and in the display area AA. The plurality of first connection lines 121 may be lines for electrically connecting the pixel driving circuit PD to other components. For example, the pixel driving circuit PD may be electrically connected to the plurality of signal lines TL and the plurality of contact electrodes CCE via the plurality of first connection lines 121. For example, the plurality of first connection lines 121 may include a (1-1)-th connection line 121a, a (1-2)-th connection line 121b, a (1-3)-th connection line 121c, and a (1-4)-th connection line 121d. However, embodiments of the present disclosure are not limited thereto.

For example, a plurality of (1-1)-th connection lines 121a may be disposed on the second protective layer 113b. The plurality of (1-1)-th connection lines 121a may be electrically connected to the pixel driving circuit PD. The plurality of (1-1)-th connection lines 121a may transmit a voltage output from the pixel driving circuit PD to the first electrode CE1 or the second electrode CE2.

For example, a third protective layer 114 may be disposed on the second protective layer 113b. The protective layer 114 may be entirely disposed in the display area AA and the non-display area NA. In the bending area BA, the third protective layer 114 may cover a side surface of the second protective layer 113b and an upper surface of the first protective layer 113a. The third protective layer 114 may be made of an organic insulating material. For example, the third protective layer 114 may be made of a photoresist, polyimide (PI), or a photo acryl-based material. However, embodiments of the present disclosure are not limited thereto. For example, the first protective layer 113a, the second protective layer 113b, and the third protective layer 114 may be made of the same material. Embodiments of the present disclosure are not limited thereto.

A plurality of (1-2)-th connection lines 121b may be disposed on the third protective layer 114. The plurality of (1-2)-th connection lines 121b may be indirectly connected to the pixel driving circuit PD or may be directly connected thereto. For example, some of the (1-2)-th connection lines 121b may be directly connected to the pixel driving circuit PD via a contact hole of the third protective layer 114. The others of the (1-2)-th connection line 121b may be electrically connected to the (1-1)-th connection line 121a via a contact hole of the third protective layer 114. However, embodiments of the present disclosure are not limited thereto. The voltage output from the pixel driving circuit PD may be transmitted to the first electrode CE1 or the second electrode CE2 via a connection line different from the plurality of (1-2)-th connection lines 121b.

A first insulating layer 115a may be disposed on the plurality of (1-2)-th connection lines 121a. The first insulating layer 115a may be entirely disposed in the display area AA and the non-display area NA. However, embodiments of the present disclosure are not limited thereto. The first insulating layer 115a may be made of an organic insulating material. However, embodiments of the present disclosure are not limited thereto. For example, the first insulating layer 115a may be made of a photo resist, polyimide (PI), or a photo acryl-based material. However, embodiments of the present disclosure are not limited thereto.

A plurality of (1-3)-th connection lines 121c may be disposed on the first insulating layer 115a. The plurality of (1-3)-th connection lines 121c may be electrically connected to the plurality of (1-2)-th connection lines 121b, respectively. For example, the (1-3)-th connection line 121c may be electrically connected to the (1-2)-th connection line 121a via a contact hole of the first insulating layer 115a.

A second insulating layer 115b may be disposed on the plurality of (1-3)-th connection lines 121b. The second insulating layer 115b may be disposed in the remaining area except for the bending area BA. However, embodiments of the present disclosure are not limited thereto. The second insulating layer 115b may be disposed in the display area AA, the first non-display area NA1, and the second non-display area NA2. However, embodiments of the present disclosure are not limited thereto. For example, a portion of the second insulating layer 115b disposed in the bending area BA may be removed. The second insulating layer 115b may be made of an organic insulating material. However, embodiments of the present disclosure are not limited thereto. For example, the second insulating layer 115b may be made of a photo resist, polyimide (PI), or a photo acryl-based material. However, embodiments of the present disclosure are not limited thereto.

A plurality of (1-4)-th connection lines 121d may be disposed on the second insulating layer 115b. The plurality of (1-4)-th connection lines 121d may be electrically connected to the plurality of (1-3)-th connection lines 121c, respectively. For example, the (1-4)-th connection line 121d may be electrically connected to the (1-3)-th connection line 121b via a contact hole of the second insulating layer 115b.

According to the present disclosure, a plurality of second connection lines 122 may be disposed on the second protective layer 113b and in the non-display area NA. The plurality of second connection lines 122 may be lines for transmitting signals transmitted from the flexible circuit board 157 and the printed circuit board 160 (see FIG. 1) to the pad PAD to the pixel driving circuit PD of the display area AA. For example, the plurality of second connection lines 122 may be electrically connected to the plurality of pad electrodes PE respectively to receive signals from the flexible circuit board (or flexible film) 157 and the printed circuit board.

For example, the plurality of second connection lines 122 may extend from the pad PAD toward the display area AA to transmit signals to the lines of the display area AA. In this case, the plurality of second connection lines 122 may function as link lines LL. The plurality of second connection lines 122 may include a (2-1)-th connection line 122a, a (2-2)-th connection line 122b, a (2-3)-th connection line 122c, and a (2-4)-th connection line 122d.

A plurality of (2-1)-th connection lines 122a may be disposed on the second protective layer 113b. The plurality of (2-1)-th connection lines 122a may extend from the second non-display area NA2 to the bending area BA and the first non-display area NA1. The plurality of (2-1)-th connection lines 122a may transmit signals transmitted from the flexible circuit board (or flexible film) 157 and the printed circuit board to the pad PAD to the pixel driving circuit PD of the display area AA. For example, the (2-1)-th connection line 122a may be electrically connected to the pixel driving circuit PD via the first connection line 121 of the display area AA. The (2-1)-th connection line 122a may be electrically connected to the second electrode CE2 via the first connection line 121 and the contact electrode CCE of the display area AA.

A plurality of (2-2)-th connection lines 122b may be disposed on the third protective layer 114. The plurality of (2-2)-th connection lines 122b may be disposed in the second non-display area NA2. The (2-2)-th connection line 122b may be electrically connected to the (2-1)-th connection line 122a via a contact hole of the third protective layer 114. Accordingly, signals from the flexible circuit board (or flexible film) 157 and the printed circuit board may be transmitted to the (2-1)-th connection line 122b via the (2-1)-th connection line 122a.

The (2-3)-th connection line 122c may be disposed on the first insulating layer 115a. The (2-3)-th connection line 122c may be disposed in the second non-display area NA2. The (2-3)-th connection line 122c may be electrically connected to the (2-2)-th connection line 122a via a contact hole of the first insulating layer 115a. Accordingly, signals from the flexible circuit board (or flexible film) 157 and the printed circuit board may be transmitted to the (2-1)-th connection line 122a via the (2-3)-th connection line 122c and the (2-2)-th connection line 122b.

The (2-4)-th connection line 122d may be disposed on the second insulating layer 115b. The (2-4)-th connection line 122d may be disposed in the second non-display area NA2. The (2-4)-th connection line 122d may be electrically connected to the (2-3)-th connection line 122b via a contact hole of the second insulating layer 115b. Accordingly, signals from the flexible film FF and the printed circuit board may be transmitted to the (2-1)-th connection line 122a via the (2-4)-th connection line 122d, the (2-3)-th connection line 122c, and the (2-2)-th connection line 122b.

Each of the plurality of first connection lines 121 and the plurality of second connection lines 122 may be made of a conductive material having excellent ductility or various conductive materials used in the display area AA. For example, the second connection line 122, a portion of which is disposed in the bending area BA, may be made of a conductive material having excellent ductility, such as gold (Au), silver (Ag), or aluminum (Al). However, embodiments of the present disclosure are not limited thereto. In another example, each of the plurality of first connection lines 121 and the plurality of second connection lines 122 may be made of molybdenum (Mo), chromium (Cr), titanium (Ti), nickel (Ni), neodymium (Nd), copper (Cu), an alloy of silver (Ag) and magnesium (Mg), or an alloy thereof. However, embodiments of the present disclosure are not limited thereto.

A third insulating layer 115c may be disposed on the plurality of first connection lines 121 and the plurality of second connection lines 122. The third insulating layer 115c may be disposed in the remaining area except for the bending area BA. However, embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be made of an organic insulating material. However, embodiments of the present disclosure are not limited thereto. For example, the third insulating layer 115c may be made of a photo resist, polyimide (PI), or a photo acryl-based material. However, embodiments of the present disclosure are not limited thereto.

In the display area AA, a plurality of banks BNK may be disposed on the third insulating layer 115c. The plurality of banks BNK may be disposed to overlap the plurality of sub-pixels, respectively. One or more light-emitting elements ED of the same type may be disposed on each of the plurality of banks BNK.

In the display area AA, the plurality of signal lines TL may be disposed on the third insulating layer 115c. The plurality of signal lines TL may be disposed in an area between adjacent ones of the plurality of banks BNK. For example, the plurality of signal lines TL may be disposed adjacent to one of the plurality of banks BNK.

The plurality of contact electrodes CCE may be disposed on the third insulating layer 115c in the display area AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from the adjacent signal line TL toward the upper portion of the bank BNK. The first electrode CE1 may be disposed on an upper surface of the bank BNK and a side surface of the bank BNK. For example, the first electrode CE1 may be disposed to extend from the signal line TL on the upper surface of the third insulating layer 115c to the side surface of the bank BNK and the upper surface of the bank BNK.

Referring to FIG. 9, the first electrode CE1 may be made of a plurality of conductive layers. For example, the first electrode CE1 may include a first conductive layer CE1a, a second conductive layer CE1b, a third conductive layer CE1c, and a fourth conductive layer CE1d. However, embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxides (ITO). However, embodiments of the present disclosure are not limited thereto.

According to the present disclosure, some conductive layers having good reflection efficiency among the plurality of conductive layers constituting the first electrode CE1 may act as an alignment key for aligning the light-emitting element ED and/or a reflective plate. For example, the second conductive layer CE1b of the plurality of conductive layers of the first electrode CE1 may include a reflective material. For example, the second conductive layer CE1b may include aluminum (Al). However, embodiments of the present disclosure are not limited thereto. Accordingly, the second conductive layer CE1b may act as the reflective plate. In addition, due to the high reflection efficiency of the second conductive layer CE1b, the second conductive layer CE1b may be easily identified in the manufacturing process, and thus the position of the light-emitting element ED or the transfer position may be aligned with the second conductive layer CE1b.

For example, in order that the second conductive layer CE1b acts as the reflective plate, a portion of each of the third conductive layer CE1c and the fourth conductive layer CE1d covering the second conductive layer CE1b may be removed or etched. For example, an upper surface of the second conductive layer CE1b may be exposed by removing or etching the portion of each of the third conductive layer CE1c and the fourth conductive layer CE1d disposed on the bank BNK. For example, a central portion and an edge portion (or a rim portion) of each of the third conductive layer CE1c and the fourth conductive layer CE1d, on which a solder pattern SDP is disposed, may be left, and the remaining portion other than the central portion and the edge portion thereof may be removed. For example, the edge portion (or the rim portion) of each of the third conductive layer CE1c made of titanium (Ti) and the fourth conductive layer CE1d made of indium tin oxide (ITO) may not be etched. This may prevent the other conductive layers of the first electrode CE1 from being corroded by a Tetramethylammonium hydroxide (TMAH) solution used in a mask process of the first electrode CE1.

As described above, the first light-emitting element 130 may be adhered to the first electrode CE1 via the solder pattern SDP.

According to the present disclosure, each of the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO), which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process thereon. However, embodiments of the present disclosure are not limited thereto.

According to the present disclosure, each of the signal line TL, the contact electrode CCE, and the pad electrode PE which are disposed at the same layer as a layer of the first electrode CE1, may be composed of multiple layers of a conductive material. However, embodiments of the present disclosure are not limited thereto. For example, each of the signal line TL, the contact electrode CCE, and the pad electrode PE may be composed of a multi-layer structure of indium tin oxide (Indium Tin Oxide, ITO) layer/titanium (Ti) layer/aluminum (Al) layer/titanium (Ti) layer. However, embodiments of the present disclosure are not limited thereto.

Each of the plurality of light-emitting elements 130, 140, and 150 may have a groove defined in a center of a bottom portion and may be bonded to the first electrode CE1 via the solder pattern SDP that fills the groove and protrudes downwardly beyond a bottom surface of each of the plurality of light-emitting elements 130, 140, and 150.

According to the present disclosure, the solder pattern SDP may be disposed on the first electrode CE1 and in each of the plurality of sub-pixels. The solder pattern SDP may bond the light-emitting element ED to the first electrode CE1 to electrically connect the light-emitting element ED to the first electrode CE1. For example, the first electrode CE1 and the anode electrode 134 of the light-emitting element ED may be electrically connected to each other via eutectic bonding using the solder pattern SDP. However, embodiments of the present disclosure are not limited thereto. For example, when the solder pattern SDP is made of indium (In) and the anode electrode 134 of the light-emitting element ED is made of gold (Au), heat and pressure may be applied thereto in the transfer process of the light-emitting element ED to bond the solder pattern SDP and the anode electrode 134 to each other. Via the eutectic bonding, the light-emitting element ED may be bonded to the solder pattern SDP and the first electrode CE1 without a separate adhesive. For example, the solder pattern SDP may be made of indium (In), tin (Sn), or an alloy thereof. However, embodiments of the present disclosure are not limited thereto. For example, the solder pattern SDP may be embodied as a bonding pad, a bonding pad, etc. However, embodiments of the present disclosure are not limited thereto.

According to the present disclosure, a passivation layer 116 may be disposed on the plurality of signal lines TL, the plurality of first electrodes CE1, the plurality of contact electrodes CCE, and the third insulating layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. Since the passivation layer 116 is disposed to cover the remaining area except for the bending area BA, an area of the plurality of pad electrodes PE, and an area of the solder pattern SDP, penetration of moisture or impurities flowing into the light-emitting element ED may be reduced. For example, the passivation layer 116 may be formed as a single layer or multiple layers made of silicon oxide (SiOx) or silicon nitride (SiNx). However, embodiments of the present disclosure are not limited thereto. For example, the passivation layer 116 may be embodied as a protective layer, an insulating layer, etc. However, embodiments of the present disclosure are not limited thereto. For example, the passivation layer 116 may have a hole defined therein exposing the solder pattern SDP.

In each of the plurality of sub-pixels, the light-emitting element ED may be disposed on the solder pattern SDP. The first light-emitting element 130 may be disposed in the first sub-pixel SP1. The second light-emitting element 140 may be disposed in the second sub-pixel SP2. The third light-emitting element 150 may be disposed in the third sub-pixel SP3. Each of the plurality of light-emitting elements 130, 140, and 150 may be embodied as a micro light-emitting element.

The light-emitting element ED may be formed on a silicon wafer using an metal organic chemical vapor deposition (MOCVD) method, a chemical vapor deposition (CVD) method, a plasma-enhanced chemical vapor deposition (PECVD) method, a molecular beam epitaxy (MBE) method, a hydride vapor phase epitaxy (HVPE) method, or sputtering method. However, embodiments of the present disclosure are not limited thereto.

Referring to FIG. 9, the first light-emitting element 130 may include an anode electrode 134, a first semiconductor layer 131, an active layer 132, a second semiconductor layer 133, a cathode electrode 135, and an encapsulation film 136. However, embodiments of the present disclosure are not limited thereto. For example, the encapsulation film 136 may not be included in the first light-emitting element 130.

The anode electrode 134 may be disposed on the solder pattern SDP. The first semiconductor layer 131 may be disposed on the anode electrode 134. The active layer 132 may be disposed on the first semiconductor layer 131. The second semiconductor layer 133 may be disposed on the active layer 132.

For example, one of the first semiconductor layer 131 and the second semiconductor layer 133 may be made of a compound semiconductor such as a group III-V, a group II-VI, or the like, and may be doped with impurities (or dopants). For example, one of the first semiconductor layer 131 and the second semiconductor layer 133 may be a semiconductor layer doped with n-type impurities, and the other thereof may be a semiconductor layer doped with p-type impurities. However, embodiments of the present disclosure are not limited thereto. For example, at least one of the first semiconductor layer 131 and the second semiconductor layer 133 may be a layer in which n-type or p-type impurities are doped in a material such as gallium nitride (GaN), gallium phosphide (GaP), gallium arsenide (GaAsP), aluminum gallium indium phosphide (AlGaInP), indium aluminum phosphide (InAlP), aluminum gallium nitride (AlGaN), aluminum indium gallium nitride (AlInN), aluminum gallium arsenide (AlGaAs), or gallium arsenide (GaAs). However, embodiments of the present disclosure are not limited thereto. For example, the n-type impurity may include silicon (Si), germanium (Ge), selenium (Se), carbon (C), tellurium (Te), tin (Sn), etc. However, embodiments of the present disclosure are not limited thereto. For example, the p-type impurity may include magnesium (Mg), zinc (Zn), calcium (Ca), strontium (Sr), barium (Ba), beryllium (Be), etc. However, embodiments of the present disclosure are not limited thereto.

For example, each of the first semiconductor layer 131 and the second semiconductor layer 133 may be made of a nitride semiconductor including n-type impurities and a nitride semiconductor including p-type impurities. However, embodiments of the present disclosure are not limited thereto. For example, the first semiconductor layer 131 may be made of a nitride semiconductor including p-type impurities, and the second semiconductor layer 133 may be made of a nitride semiconductor including n-type impurities. However, embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 to emit light. For example, the active layer 132 may be composed of one of a single well structure, a multiple well structure, a single quantum well structure, a multi-quantum well (MQW) structure, a quantum dot structure, and a quantum wire structure. However, embodiments of the present disclosure are not limited thereto. For example, the active layer 132 may be made of indium gallium nitride (InGaN) or gallium nitride (GaN). However, embodiments of the present disclosure are not limited thereto.

In another example, the active layer 132 may include a MQW (multi quantum well) structure having a well layer and a barrier layer having a higher band gap than that of the well layer. For example, the active layer 132 may include InGaN as a material of the well layer and AlGaN as a material of the barrier layer. However, embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1 to each other. The anode voltage output from the pixel driving circuit PD may be applied to the first semiconductor layer 131 via the signal line TL, the first electrode CE1, and the anode electrode 134. For example, the anode electrode 134 may be made of a conductive material capable of eutectic bonding with the solder pattern SDP. However, embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof. However, embodiments of the present disclosure are not limited thereto.

The cathode electrode 135 may be disposed on the second semiconductor layer 133. For example, the cathode electrode 135 may electrically connect the second semiconductor layer 133 and the second electrode CE2 to each other. The cathode voltage output from the pixel driving circuit PD may be applied to the second semiconductor layer 133 via the contact electrode CCE, the second electrode CE2, and the cathode electrode 135. The cathode electrode 135 may be made of a transparent conductive material so that light emitted from the light-emitting element ED may be directed upwardly of the light-emitting element ED. However, embodiments of the present disclosure are not limited thereto. For example, the cathode electrode 135 may be made of a material such as Indium Tin Oxide (ITO), Indium Zinc Oxide (IZO), or Indium Gallium Zinc Oxide (IGZO). However, embodiments of the present disclosure are not limited thereto.

The encapsulation film 136 may be disposed on at least a portion of each of the first semiconductor layer 131, the active layer 132, the second semiconductor layer 133, the anode electrode 134, and the cathode electrode 135. For example, the encapsulation film 136 may surround at least a portion of each of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a portion of each of the anode electrode 134 and the cathode electrode 135, for example, an edge portion (or one side surface) of the anode electrode 134 and an edge portion (or one side surface) of the cathode electrode 135. At least a portion of the anode electrode 134 may not be covered with the encapsulation film 136 such that the anode electrode 134 and the solder pattern SDP are connected to each other. For example, at least a portion of the cathode electrode 135 may not be covered with the encapsulation film 136 such that the cathode electrode 135 and the second electrode CE2 are connected to each other. For example, the encapsulation film 136 may be made of an insulating material such as silicon nitride (SiNx) or silicon oxide (SiOx). However, embodiments of the present disclosure are not limited thereto.

In another example, the encapsulation film 136 may have a structure in which a reflective material is dispersed in a resin layer. However, embodiments of the present disclosure are not limited thereto. For example, the encapsulation film 136 may be embodied as a reflector having various structures. However, embodiments of the present disclosure are not limited thereto. Light emitted from the active layer 132 may be reflected upwardly from the encapsulation film 136, thereby improving light extraction efficiency. For example, the encapsulation film 136 may be a reflective layer. However, embodiments of the present disclosure are not limited thereto.

According to the present disclosure, an example in which the light-emitting element ED has a vertical structure has been described. However, embodiments of the present disclosure are not limited thereto. For example, the light-emitting element ED may have a lateral structure or a flip chip structure.

Although the first light-emitting element 130 has been described with reference to FIG. 9, each of the second light-emitting element 140 and the third light-emitting element 150 may have substantially the same structure as that of the first light-emitting element 130. For example, the first semiconductor layer, the active layer, the second semiconductor layer, the anode electrode, the cathode electrode, and the encapsulation film of each of the second light-emitting element 140 and the third light-emitting element 150 may be substantially the same as the first semiconductor layer 131, the active layer 132, the second semiconductor layer 133, the anode electrode 134, the cathode electrode 135, and the encapsulation film 136 of the first light-emitting element 130, respectively.

The optical insulating layer 117 may include a first optical layer 117a, a second optical layer 117b, and a third optical layer 117c.

According to the present disclosure, the first optical layer 117a surrounding the plurality of light-emitting elements ED may be disposed in the display area AA. For example, the first optical layer 117a may be disposed to cover the plurality of light-emitting elements ED and the bank BNK in the areas of the plurality of sub-pixels. For example, the first optical layer 117a may cover the bank BNK, a portion of the passivation layer 116, and an area between adjacent ones of the plurality of light-emitting elements ED. The first optical layer 117a may be disposed in or cover an area between adjacent ones of the plurality of light-emitting elements ED included and an area between adjacent ones of the plurality of banks BNK in one pixel PX. For example, the first optical layer 117a may extend in the first direction X and the first optical layers 117a may be spaced apart from each other in the second direction Y. For example, the first optical layer 117a may be disposed between the passivation layer 116 and the second electrode CE2 so as to surround the side of each of the light-emitting element ED and the bank BNK. However, embodiments of the present disclosure are not limited thereto. For example, the first optical layer 117a may act as a diffusion layer, a sidewall diffusion layer, etc. However, embodiments of the present disclosure are not limited thereto.

The first optical layer 117a may include an organic insulating material in which fine particles are dispersed. However, embodiments of the present disclosure are not limited thereto. For example, the first optical layer 117a may be made of siloxane in which fine metal particles such as titanium dioxide (TiO2) particles are dispersed. However, embodiments of the present disclosure are not limited thereto. Light from the plurality of light-emitting elements ED may be scattered by the fine particles dispersed in the first optical layer 117a and then emitted out of the display device 1000. Accordingly, the first optical layer 117a may improve extraction efficiency of light emitted from the plurality of light-emitting elements ED.

For example, the first optical layer 117a may be disposed in each of the plurality of pixels PX or may be commonly disposed in some pixels PX arranged in the same row. However, embodiments of the present disclosure are not limited thereto. For example, the first optical layer 117a may be disposed in each of the plurality of pixels PX, or the plurality of pixels PX may share one first optical layer 117a with each other. In another example, each of the plurality of sub-pixels SP may separately include the first optical layer 117a. However, embodiments of the present disclosure are not limited thereto.

According to the present disclosure, the second optical layer 117b may be disposed on the passivation layer 116 and in the display area AA. For example, the second optical layer 117b may be disposed to surround the first optical layer 117a. For example, the second optical layer 117b may be in contact with a side surface of the first optical layer 117a. For example, the second optical layer 117b may be disposed in an area between adjacent ones of the plurality of pixels PX. However, embodiments of the present disclosure are not limited thereto. For example, the second optical layer 117b may act as a diffusion layer, a diffusion layer window, a window diffusion layer, etc. However, embodiments of the present disclosure are not limited thereto.

The second optical layer 117b may be made of an organic insulating material. However, embodiments of the present disclosure are not limited thereto. The second optical layer 117b may be made of the same material as that of the first optical layer 117a. However, embodiments of the present disclosure are not limited thereto. For example, the first optical layer 117a may include fine particles, and the second optical layer 117b may not include fine particles. For example, the second optical layer 117b may be made of siloxane. However, embodiments of the present disclosure are not limited thereto.

For example, a thickness of the first optical layer 117a may be smaller than a thickness of the second optical layer 117b. However, embodiments of the present disclosure are not limited thereto. Accordingly, in a cross-sectional view of the device, an area in which the first optical layer 117a is disposed may include a concave portion recessed downwardly beyond an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE via a contact hole of the second optical layer 117b. For example, the second electrode CE2 may be disposed on the plurality of light-emitting elements ED. For example, the second electrode CE2 may include a transparent conductive oxide such as indium tin oxide (ITO) or indium zinc oxide (IZO). However, embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover a flat upper surface of an outer portion of the first optical layer 117a.

The second electrode CE2 may continuously extend in the first direction of the substrate 110. Accordingly, the plurality of pixels PX arranged in the first direction of the substrate 110 may be commonly connected to the second electrode CE2. For example, the second electrode CE2 may be commonly connected to the plurality of pixels PX.

According to the present disclosure, the second electrode CE2 may continuously extend across the first optical layer 117a, the second optical layer 117b, and the plurality of light-emitting elements ED. An area in which the first optical layer 117a is disposed may include the concave portion recessed downwardly beyond the upper surface of the second optical layer 117b. Accordingly, since a first portion of the second electrode CE2 disposed on the first optical layer 117a is disposed along and on the concave portion, a vertical level of the first portion may be lower than a vertical level of a second portion of the second electrode CE2 disposed on the second optical layer 117b.

The third optical layer 117c may be disposed on the second electrode CE2. The third optical layer 117c may be disposed to overlap the plurality of light-emitting elements ED and the first optical layer 117a. Since the third optical layer 117c is disposed on the second electrode CE2 and the plurality of light-emitting elements ED, a mura that may occur in some of the plurality of light-emitting elements ED may be suppressed. For example, when the plurality of light-emitting elements ED are transferred onto the substrate 110 of the display device 1000, an area in which spacings between adjacent ones of the plurality of light-emitting elements ED are not uniform may occur due to process variations or etc. When the spacings between adjacent ones of the plurality of light-emitting elements ED are non-uniform, respective light emission areas of the plurality of light-emitting elements ED may be non-uniformly arranged, and thus, the mura may be visually recognized by the user. Accordingly, since the third optical layer 117c configured to uniformly diffuse light is formed on top of the plurality of light-emitting elements ED, a phenomenon that the light emitted from some light-emitting elements ED is visible as the mura to the user may be suppressed. Accordingly, the light emitted from the plurality of light-emitting elements ED may be uniformly diffused by the third optical layer 117c and then be extracted out of the display device 1000, such that the luminance uniformity of the display device 1000 may be improved.

The third optical layer 117c may be made of an organic insulating material in which fine particles are dispersed. However, an embodiment of the present disclosure is not limited thereto. For example, the third optical layer 117c may be made of siloxane in which fine metal particles such as titanium dioxide (TiO2) particles are dispersed. However, embodiments of the present disclosure are not limited thereto. For example, the third optical layer 117c may be made of the same material as that of the first optical layer 117a. However, embodiments of the present disclosure are not limited thereto. For example, the third optical layer 117c may act as a diffusion layer, an upper surface diffusion layer, etc. However, embodiments of the present disclosure are not limited thereto.

According to the present disclosure, light from the plurality of light-emitting elements ED may be scattered by the fine particles dispersed in the third optical layer 117c and be emitted out of the display device 1000. The third optical layer 117c may evenly mix light beams respectively emitted from the plurality of light-emitting elements ED with each other to further improve luminance uniformity of the display device 1000. In addition, light extraction efficiency of the display device 1000 may be improved by the light being scattered from the plurality of fine particles, and accordingly, the display device 1000 may operate at a low power level.

A black matrix BM may be disposed on the second electrode CE2, the first optical layer 117a, the second optical layer 117b, and the third optical layer 117c and in the display area AA. For example, the black matrix BM may fill a contact hole of the second optical layer 117b. Since the black matrix BM is constructed to cover the display area AA, the black matrix may reduce color mixing between light beams from the plurality of sub-pixels and may prevent or reduce external light reflection. For example, since the black matrix BM is also disposed in the contact hole via which the second electrode CE2 and the contact electrode CCE are connected to each other, light leakage between adjacent ones of the plurality of sub-pixels may be prevented or reduced.

For example, the black matrix BM may be made of an opaque material. However, embodiments of the present disclosure are not limited thereto. For example, the black matrix BM may be made of an organic insulating material to which a black pigment or a black dye is added. However, embodiments of the present disclosure are not limited thereto.

A cover layer 118 may be disposed on the black matrix BM and in the display area AA. The cover layer 118 may protect the components under the cover layer 118. For example, the cover layer 118 may be made of an organic insulating material. However, embodiments of the present disclosure are not limited thereto. For example, the cover layer 118 may be made of a photoresist, polyimide (PI), or a photo acryl-based material. However, embodiments of the present disclosure are not limited thereto. For example, the cover layer 118 may be embodied as an overcoat layer, an insulating layer, etc. However, embodiments of the present disclosure are not limited thereto.

The polarizing layer 293 may be disposed on the cover layer 118 via a first adhesive layer 291. The cover member 155 may be disposed on the polarizing layer 293 via a second adhesive layer 295. For example, each of the first adhesive layer 291 and the second adhesive layer 295 may include an OCA (optically clear adhesive), an OCR (optically clear resin), a PSA (pressure sensitive adhesive), etc. However, embodiments of the present disclosure are not limited thereto.

According to the present disclosure, the plurality of pad electrodes PE may be disposed on the third insulating layer 115c and in the second non-display area NA2. For example, at least a portion of each of the plurality of pad electrodes PE may not be covered with the passivation layer 116 so as to be exposed. For example, the plurality of pad electrodes PE may be electrically connected to the (2-4)-th connection line 122c via a contact hole of the third insulating layer 115d.

An adhesive layer ACF may be disposed on the plurality of pad electrodes PE. The adhesive layer ACF may be an adhesive layer in which conductive balls are dispersed in an insulating material. However, embodiments of the present disclosure are not limited thereto. When heat or pressure is applied to the adhesive layer ACF, the conductive balls may be electrically connected to each other in an area to which the heat or pressure has been applied such that the adhesive layer ACF may be conductive. The adhesive layer ACF may be disposed between the plurality of pad electrodes PE and the flexible circuit board (or flexible film) 157 to attach or bond the flexible circuit board (or flexible film) 157 to the plurality of pad electrodes PE. For example, the adhesive layer ACF may be embodied as an anisotropic conductive film (ACF). However, embodiments of the present disclosure are not limited thereto.

The flexible circuit board (or flexible film) 157 may be disposed on the adhesive layer ACF. The flexible circuit board (or flexible film) 157 may be electrically connected to the plurality of pad electrodes PE via the adhesive layer ACF. Accordingly, the signals output from the flexible circuit board (or flexible film) 157 and the printed circuit board may be transmitted to the pixel driving circuit PD of the display area AA via the plurality of pad electrodes PE, the (2-4)-th connection line 122d, the (2-3)-th connection line 122c, the (2-1)-th connection line 122b, and the (2-1)-th connection line 122a.

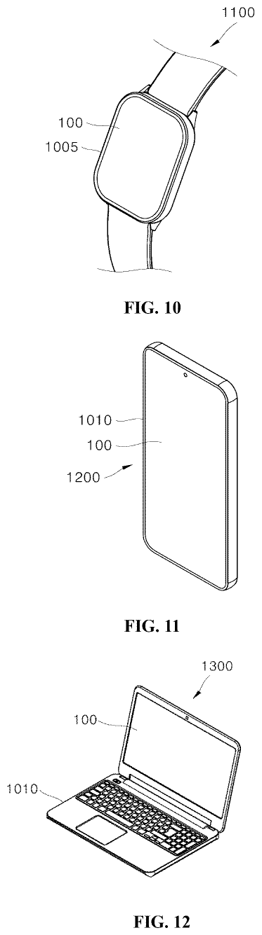

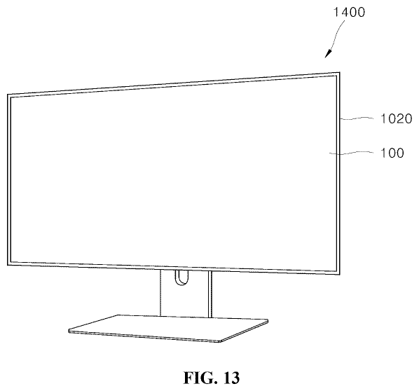

FIGS. 10 to 13 are diagrams illustrating an apparatus to which a display device according to embodiments of the present disclosure is applied.

Referring to FIGS. 10 to 13, a display device 1000 according to embodiments of the present disclosure may be included in various apparatus or electronic devices. For example, referring to FIGS. 10 to 13, various electronic devices may include a wearable device 1100, a mobile device 1200, a notebook computer 1300, and a monitor or TV 1400. However, embodiments of the present disclosure are not limited thereto.

Each of the wearable device 1100, the mobile device 1200, the notebook computer 1300, and the monitor or TV 1400 may respectively include a casing 1005, 1010, 1015, or 1020 and the display device 1000 including the display panel 100 and according to embodiments of the present disclosure as described above with reference to FIGS. 1 to 9.

For example, the display device according to an embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), a MP3 player, a mobile medical device, a desktop PC, a laptop PC, a netbook computer, a workstation, a navigation system, a vehicle display device, a theater display device, a television, a wall paper device, a signage device, a game device, a notebook computer, a monitor, a camera, a camcorder, a home appliance, etc.

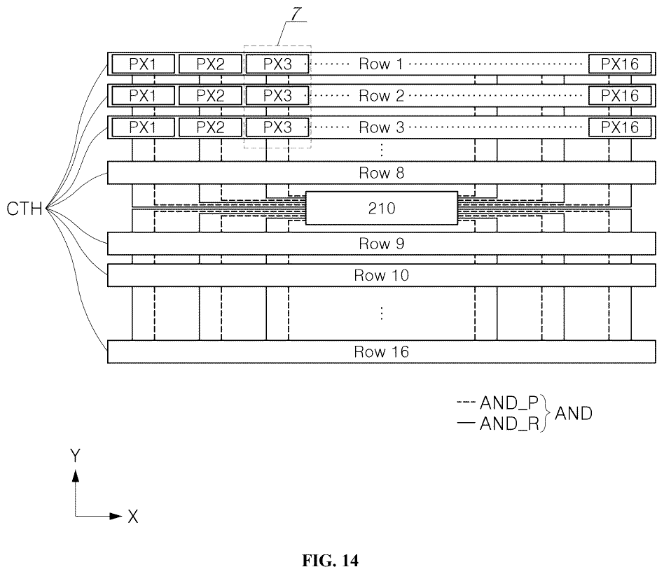

FIG. 14 is a plan view illustrating an area in which one pixel driving circuit among a plurality of pixel driving circuits is disposed according to one embodiment of the present disclosure.

Referring to FIGS. 3, 5, and 14 together, in a display device according to another embodiment of the present disclosure, a plurality of pixels PX1, PX2, PX3 . . . PX16 including a plurality of driving chips 210 as the pixel driving circuits and the plurality of light-emitting elements electrically connected to the driving chips 210 may be arranged.

For example, the first to 16th pixels PX1 to PX16 may be arranged in the row direction as the first direction. One pixel PX may include red (R), green (G), and blue (B) sub-pixels.

A plurality of light-emitting elements may be disposed in each of the sub-pixels. At least one light-emitting element may be disposed in one sub-pixel. For example, two light-emitting elements may be disposed in one sub-pixel. One of the two light-emitting elements may act as a main light-emitting element, and the other thereof may act as a redundant light-emitting element. The light-emitting element may be embodied as a micro LED (LED). Accordingly, the red (R), green (G), and blue (B) sub-pixels may be repeatedly arranged in this order in the first direction, that is, the row direction.

In addition, the sub-pixels emitting light of the same color may be arranged in the column direction as the second direction. For example, the sub-pixels emitting light of one color among red (R), green (G), and blue (B) colors may be arranged in the column direction as the second direction. The sub-pixels emitting light of the same color may be electrically connected to each other via one first electrode AND_P and AND_R.

The first electrode AND may include a first line AND_P and a second line AND_R. The first line AND_P and the second line AND_R may be spaced apart from each other in the first direction DR1 of the substrate 200. The first line AND_P of the first electrode AND may be connected to the main light-emitting element, and the second line AND_P of the first electrode AND may be connected to the redundant light-emitting element.

Each of a plurality of second electrodes CTH may extend in the first direction. In addition, the plurality of second electrodes CTH may be arranged to be spaced apart from each other in the second direction. Accordingly, each of the second electrodes CTH may extend in the first direction and may be connected to the first pixel PX1 to the 16th pixel PX16 arranged in each of a plurality of rows Row 1, Row2, Row 3, . . . , Row 16.

Each of the plurality of driving chips 210 may include a plurality of driving circuits to drive the plurality of light-emitting elements. One driving chip 210 may be connected to the plurality of first electrodes AND and the plurality of second electrodes CTH respectively connected to the plurality of pixels PX1, PX2, PX3, . . . , PX16. For example, one driving chip 210 may drive the plurality of light-emitting elements arranged in the first row Row 1 to the 16th row Row 16. In other words, one driving chip 210 may be electrically connected to the plurality of light-emitting elements arranged in the first row Row 1 to the 16th row Row 16 via the first electrodes AND and the second electrodes CTH, and may supply a control signal and power thereto via the first electrodes AND and the second electrodes CTH to control the light-emitting operations of the plurality of light-emitting elements.

A display device according to another embodiment of the present disclosure operates in a touch sensing manner. The touch sensing manner may include the touch sensing scheme of a capacitance substrate which may include a self-capacitance operation scheme and a mutual capacitance operation scheme for sensing a touch based on a detecting result of a change in a capacitance between two types of touch sensors.

The display device 1000 according to an embodiment of the present disclosure may perform the touch operation and the touch sensing in the self-capacitance-based touch sensing scheme, or may perform the touch operation and the touch sensing in the mutual-capacitance-based touch sensing scheme.

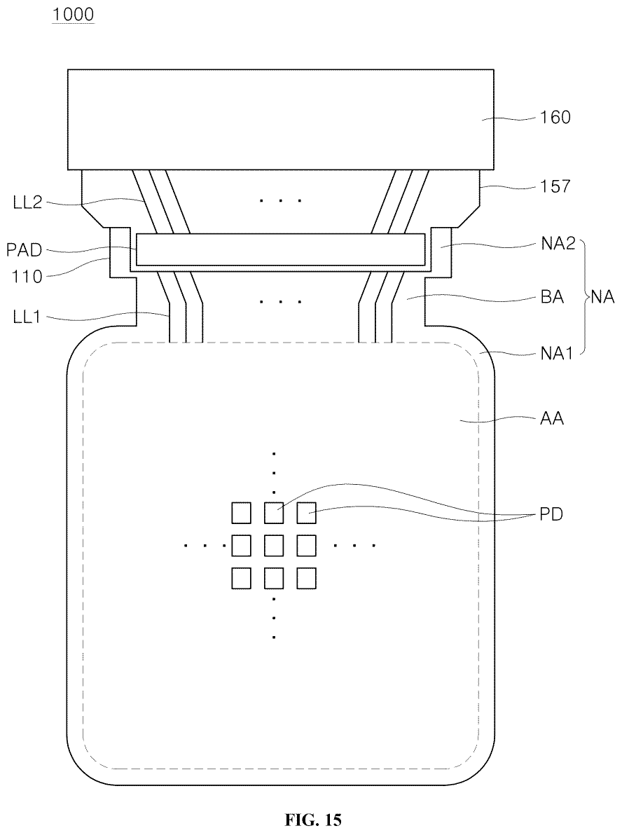

Referring to FIG. 15, in a display device 1000 according to an embodiment of the present disclosure, a plurality of driving chips PD may be disposed in a display area AA, and a pad PAD may be disposed in a non-display area NA.

The pad PAD may be connected to the display area AA via a plurality of first link lines LL1 and may be connected to the printed circuit board 160 via a plurality of second link lines LL2. The first link line LL1 may be routed via a base metal line M0 and a first metal line M1. Accordingly, the first link line LL1 may be made of the same material as that of and be disposed in the same layer as that of the base metal line M0 and the first metal line M1 disposed in the display area AA. The base metal line M0 and the first metal line M1 may be made of a metal material of titanium (Ti), aluminum (Al), and titanium (Ti). The second link line LL2 may be routed via the base metal line M0, the first metal line M1, and the third metal line M3. Accordingly, the second link line LL2 may be made of the same material as that of and be disposed in the same layer as that of the base metal line M0, the first metal line M1, and the third metal line M3 disposed in the display area AA. The third metal line M3 may also be made of a metal material of titanium (Ti), aluminum (Al), or titanium (Ti). Each of the base metal line M0 and the first metal line M1 to the third metal line M3 may have a width of about 2.5 to about 7.5 micrometers (μm). However, embodiments of the present disclosure are not limited thereto.

The printed circuit board 160, as shown in FIG. 2 may be a component electrically connected to one or more flexible circuit boards (or flexible films) 157 and configured to supply signals to the driving chip PD. The printed circuit board 160 may be disposed on one side of the flexible circuit board (or flexible film) 157 so as to be electrically connected to the flexible circuit board (or flexible film) 157. The printed circuit board 160 may be disposed in the same layer as that of the fourth metal line M4. The printed circuit board 160 may be routed via the base metal line M0 and the first metal line M1. The printed circuit board 160 is provided with various components. The printed circuit board 160 is provided with Various components for supplying various signals to the driving chip PD. For example, the printed circuit board 160 may be provided with the various components including a timing controller, a power supply, a memory, a processor, or the like. For example, the printed circuit board 160 may include a power management integrated circuit (PMIC). However, embodiments of the present disclosure are not limited thereto.

The pad PAD may include the pad electrodes PE of FIG. 2 electrically connected to the plurality of light-emitting elements PX.

The power signals may be directly applied from the pad PAD to the plurality of driving chips PD. For example, power signals such as a high potential power (VDD) signal and a low potential power (VSS) signal may be applied to the pad PAD from the printed circuit board 160 via the plurality of second link lines LL2, and may be applied to each driving chip PD of the display area AA from the pad PAD via the plurality of first link lines LL1.

In this regard, the power signals may include, for example, a high potential power (VDD) signal, a low potential power (VSS) signal, a ground power (VG) signal, a precharge power (VPCH) signal, a bias power (VBIAS) signal, a reset power (VRESET) signal, an initialization power (VINI) signal, a reference power (VREF) signal, and a driving power (VDRV) signal.

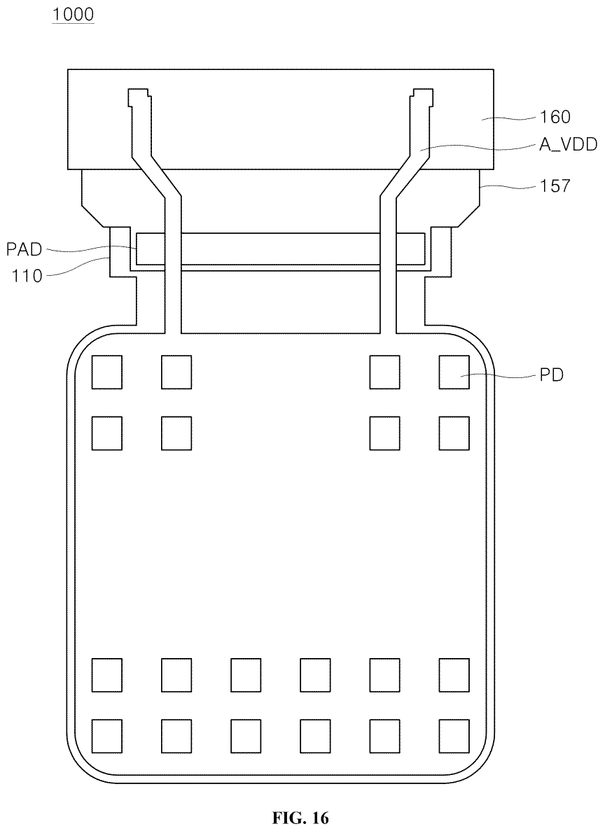

Referring to FIG. 16, in the display device 1000 according to an embodiment of the present disclosure, a high-potential power signal A_VDD from the printed circuit board 160 may be applied to a plurality of driving chips PD.

The high potential power signal A_VDD may be applied to the plurality of driving chips PD via, for example, a plate-shaped electrode plate in the display area AA. In this regard, the plate-shaped electrode plate may be made of the same material as that of and be disposed in the same layer as that of one of the base metal lines M0 to the second metal lines M2 disposed in the display area AA. Each of the base metal line M0 to the second metal line M2 may be made of a metal material of titanium (Ti), aluminum (Al), or titanium (Ti).

The high potential power signal A_VDD may be applied from the printed circuit board 160 to the plurality of driving chips PD via the pad PAD of the flexible printed circuit board 157.

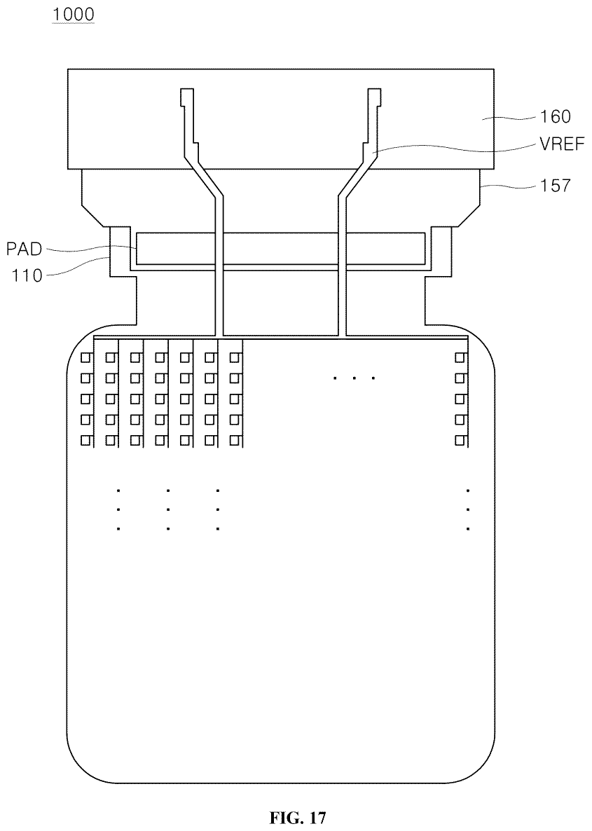

Referring to FIG. 17, in the display device 1000 according to an embodiment of the present disclosure, a reference power signal VREF from the printed circuit board 160 may be applied to the plurality of driving chips PD. The reference power signal VREF may be applied to the plurality of driving chips PD via one of the base metal lines M0 to M4.

Accordingly, the metal line for applying the reference power signal VREF may be made of the same material as that of and be disposed in the same layer as that of one of the base metal lines M0 to the fourth metal line M4 disposed in the display area AA. The base metal line M0 to the third metal line M3 may be the same as described above, and the fourth metal line M4 may be made of a metal material of Indium Tin Oxide (ITO), titanium (Ti), aluminum (Al), or titanium (Ti). The metal line for supplying the reference power signal VREF may have a width of about 2.5 micrometers to about 7.5 micrometers (μm). However, embodiments of the present disclosure are not limited thereto.

The reference power signal VREF may be applied from the printed circuit board 160 to the plurality of driving chips or the plurality of light-emitting elements via the pad PAD of the flexible printed circuit board 157.

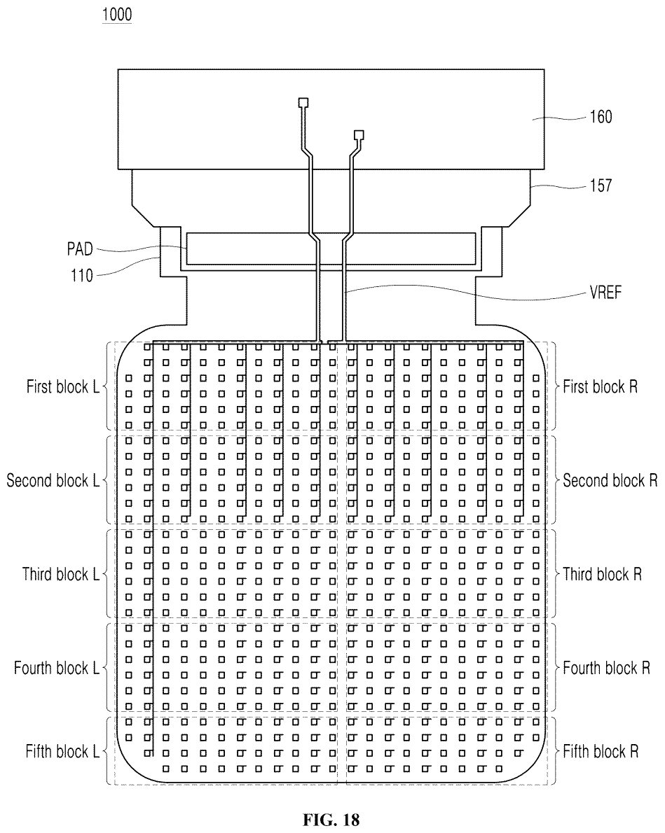

Referring to FIG. 18, in the display device 1000 according to an embodiment of the present disclosure, a plurality of block areas (first block L to fifth block L, first block R to fifth block R) may be disposed in both sides around a central column virtual line in the display area AA and may be arranged in a symmetrical manner with each other around the central column virtual line.

In the display area AA, the first block L to the fifth block L may be disposed in the left side around the central column virtual line, and the first block R to the fifth block RL may be disposed in the right side around the central column virtual line.

That is, in the display area AA, a first block R in the right side may be disposed to correspond to a first block L in the left side around the central column virtual line, a second block R in the right side may be disposed to correspond to a second block L in the left side around the central column virtual line, a third block R in the right side may be disposed to correspond to a third block L in the left side around the central column virtual line, a fourth block R in the right side may be disposed to correspond to a fourth block L in the left side around the central column virtual line, and a fifth block R in the right side may be disposed to correspond to a fifth block L in the left side around the central column virtual line.

Therefore, in the display device 1000 according to an embodiment of the present disclosure, the data signal VDATA and the clock signal CLK from the pad PAD may be applied to the plurality of driving chips PD in each of the block areas.

Among the plurality of block areas arranged in the column direction and disposed in the same side of both opposing sides (left and right sides) around the central column virtual line, one block area may be connected to a next block area via a connection line NFC_BUF. The connection line NFC_BUF may be one of the base metal lines M0 to the fourth metal line M4. Accordingly, the connection line NFC_BUF may be made of the same material as that of and be disposed in the same layer as that of one of the base metal lines M0 to the fourth metal line M4 disposed in the display area AA. The materials of the base metal line M0 to the fourth metal line M4 are the same as described above. The connection line NFC_BUF may have a width of about 2.5 micrometers to 7.5 micrometers (μm). However, embodiments of the present disclosure are not limited thereto.

The data signal and the clock signal are applied to a first block area among the plurality of block areas arranged in the column direction and disposed in the same side of both opposing sides (left and right sides) around the central column virtual line and subsequently, are applied from the first block area to a second block area among the plurality of block areas arranged in the column direction via a first connection line. Then, the data signal and the clock signal are applied from the second block area to a third block area among the plurality of block areas arranged in the column direction via a second connection line. In this way, the data signal and the clock signal are applied from a (n−1)-th block area to a n-th block area among the plurality of block areas arranged in the column direction via a second connection line.

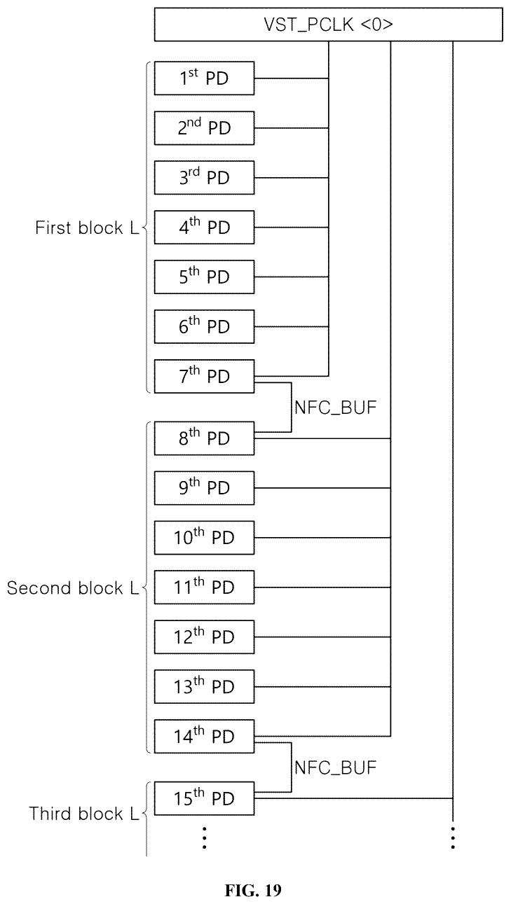

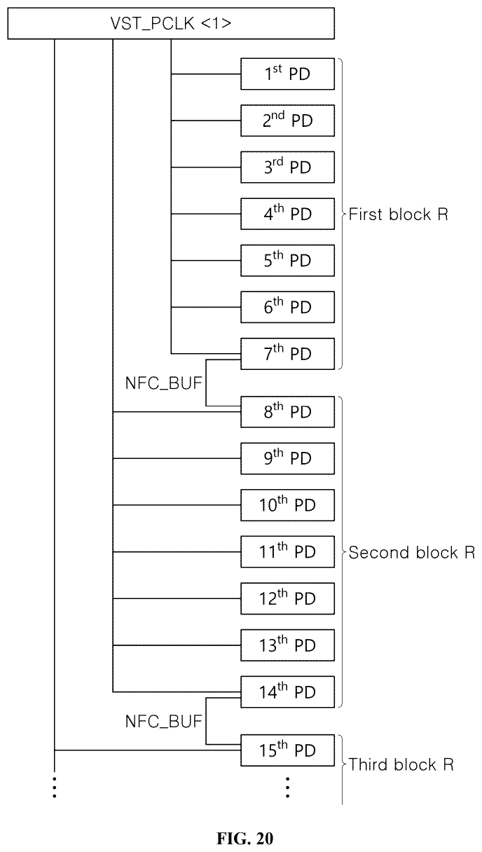

Referring to FIGS. 19 and 20, the clock signal VST_PCLK may include a low-level signal 0 and a high-level signal 1. The low-level signal 0 of the clock signal VST_PCLK may be applied to the plurality of block areas arranged in the column direction and disposed in the left side around the central column virtual line, while the high-level signal 1 of the clock signal VST_PCLK may be applied to the plurality of block areas arranged in the column direction and disposed in the right side around the central column virtual line.

The first block L in the left side around the central column virtual line includes a first driving chip 1st PD to a seventh driving chip 7th PD, and the second block L in the left side around the central column virtual line includes the eighth driving chip 8th PD to the 14th driving chip 14th PD. In this way, seven driving chips may be disposed in each of the block areas in the left side around the central column virtual line.

The first block R in the right side around the central column virtual line includes the first driving chip 1st PD to the seventh driving chip 7th PD, and the second block R in the right side around the central column virtual line includes the eighth driving chip 8th PD to the 14th driving chip 14th PD. In this way, seven driving chips may be disposed in each of the block areas in the right side around the central column virtual line.

The seventh driving chip 7th PD in the first block L in the left side around the central column virtual line may be connected to the eighth driving chip 8th PD in the second block L in the left side around the central column virtual line via the first connection line NFC_BUF. The 14th driving chip 14th PD in the second block L in the left side around the central column virtual line may be connected to the 21th driving chip 21th PD in the third block L in the left side around the central column virtual line via the second connection line NFC_BUF. In this way, all driving chips in all of the blocks in the left side around the central column virtual line may be connected to each other.

In a similar manner, the seventh driving chip 7th PD in the first block L in the right side around the central column virtual line may be connected to the eighth driving chip 8th PD in the second block L in the right side around the central column virtual line via the first connection line NFC_BUF. The 14th driving chip 14th PD in the second block L in the right side around the central column virtual line may be connected to the 21th driving chip 21th PD in the third block L in the right side around the central column virtual line via the second connection line NFC_BUF. In this way, all driving chips in all of the blocks in the right side around the central column virtual line may be connected to each other.

Referring to FIG. 15, in the display device 1000 according to an embodiment of the present disclosure, the printed circuit board 160 may be disposed in the non-display area NA. The printed circuit board 160 may be connected to the pad PAD via the plurality of second link lines LL2. The display area AA may be connected to the pad PAD via the plurality of first link lines LL1.

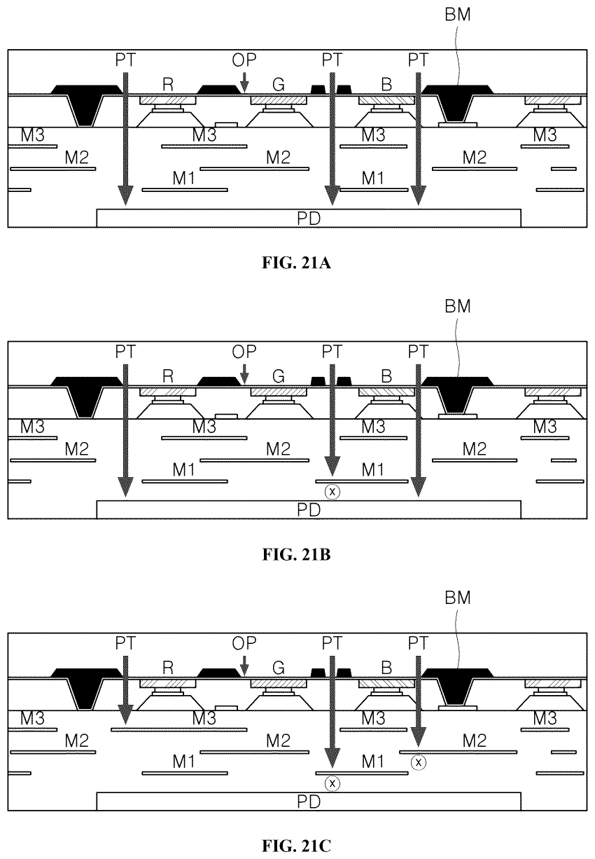

Referring to FIGS. 8 and 21A-21C, in the display device according to an embodiment of the present disclosure, the protective layers 113a and 113b are disposed on the substrate 110. The base metal line 121a or M0 is disposed on the protective layer. The third protective layer 114 is disposed on the protective layer and the base metal line. The first metal line 121b or M1 is disposed on the third protective layer 114. The first insulating layer 115a is disposed on the third protective layer and the first metal line. The second metal line 121c or M2 is disposed on the first insulating layer. The second insulating layer 115b is disposed on the first insulating layer and the second metal line. The third metal line 121d or M3 is disposed on the second insulating layer. The third insulating layer 115c is disposed on the second insulating layer and the third metal line. The fourth metal line CCE or M4 are disposed on the third insulating layer 115c.

The second metal line 121c or M2 may have a triple layer structure of titanium (Ti) layer/aluminum (Al) layer/titanium (Ti) layer. However, embodiments of the present disclosure are not limited thereto. The fourth metal line CCE or M4 may have a quadruple structure of indium tin oxide (ITO) layer/titanium (Ti) layer/aluminum (Al) layer/titanium (Ti) layer. However, embodiments of the present disclosure are not limited thereto. In this regard, in the second metal line 121c or M2 and the fourth metal line CCE or M4, the thickness of the aluminum (Al) layer may be reduced by one half to improve total thickness variation (TTV).

The base metal line 121a or M0 and the third metal line 121d or M3 are connected to many sensor and thus the thickness thereof may not be reduced. The base metal line 121a or M0, the first metal line 121b or M1 and the third metal line 121d or M3 may be used for signal wiring routing, and thus, the thickness thereof may not be reduced because the resistance thereof may increase when the thickness thereof is reduced.

In the pad PAD, the fourth metal line M4 constitutes the pad electrode PE and may be routed via the base metal line M0 and the first metal line ML.

The plurality of first link lines LL1 may be routed via the base metal line M0, the first metal line M1, and the third metal line M3.

The power signals may be applied to the display area AA from the pad PAD via the dual metal line including the base metal line M0 and the first metal line M1.

The data signal and the clock signal may be applied from the pad PAD to the display area AA via the third metal line M3.

The bending area BA may be disposed between the pad PAD and the display area AA, and the bending area BA may be routed via the base metal line M0.

Referring to FIGS. 8 and 21A-21C, in the display device according to the embodiment of the present disclosure, a plurality of openings OP may be defined so as to correspond to the plurality of light-emitting elements R, G, and B, respectively.

That is, the black matrix BM may have the plurality of openings OP defined therein such that the plurality of light-emitting elements R, G, and B may be exposed through the plurality of openings OP, respectively, in the black matrix BM masking process. Each of the light-emitting elements R, G, and B may be exposed through each opening OP defined between spaced and adjacent portions of the black matrix BM. In this regard, a slight gap may be generated between each of the light-emitting elements R, G, and B and the black matrix B in an area of each of the openings OP.

Accordingly, as shown in FIG. 21A, light or photons PT from the outside may travel through the slight gap defined between each of the light-emitting elements R, G, and B and the black matrix B in an area of each opening OP so as to reach the driving chip PD.

In order to prevent or reduce the external light from being applied to the driving chip PD, each of the first metal line M1 to the third metal line M3 may be disposed in an area between the driving chip PD and the plurality of light-emitting elements R, G, and B in the vertical direction so as to overlap each of the plurality of openings OP in the vertical direction. That is, each of the first metal line M1 to the third metal line M3 may be disposed in the area of each opening OP in the plan view so as to overlap the gap defined between each of the light-emitting elements R, G, and B and the black matrix B. In addition, each of the first metal line M1 to the third metal line M3 may be disposed to overlap each opening OP in the plan view so as to cover an entirety of the driving chip PD exposed through the openings OP.

As shown in FIG. 21B, the light PT incident from the outside through each opening OP may be blocked with the first metal line M1 and thus may be prevented from being applied to the driving chip PD.

As shown in FIG. 21C, the light PT incident from the outside through each opening OP may be blocked with the first metal line M1, the second metal line M2, and the third metal line M3, and thus may be prevented from being applied to the driving chip PD.

Referring to FIGS. 21A-21C, a hole h may be defined between adjacent portions of the black matrix BM.

Accordingly, the light PT may be incident from the outside through the hole h and may be applied to the driving chip PD.

Accordingly, each of the first metal line M1 to the third metal line M3 may be disposed to overlap the hole h vertically while being disposed between the driving chip PD and the plurality of light-emitting elements R, G, and B in the vertical direction.

The first metal line M1 to the third metal line M3 disposed to overlap the hole h vertically may prevent or reduce the light PT incident thereto from the outside through the hole h from being applied to the driving chip PD.

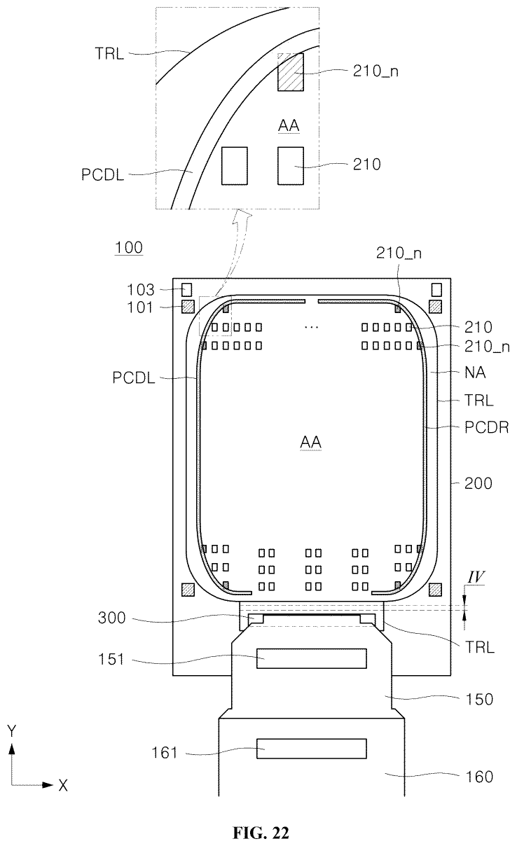

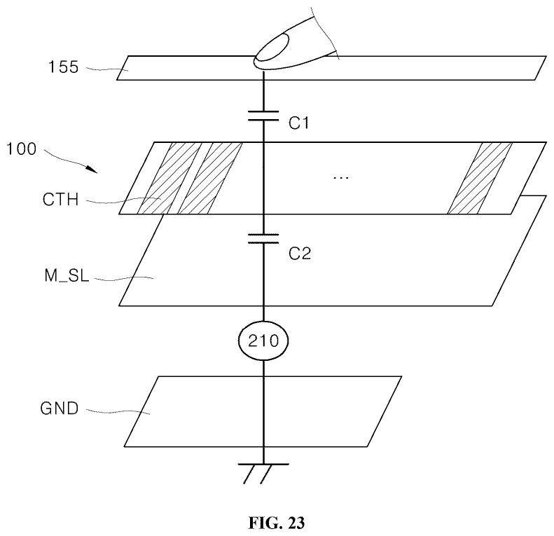

FIG. 22 is a plan view of a display device according to another embodiment of the present disclosure. FIG. 23 is a view illustrating a touch operation of a display device according to another embodiment of the present disclosure.

Referring to FIG. 22, in a display area AA of a substrate 200 according to another embodiment of the present disclosure, a plurality of pixels PX1, PX2, PX3, . . . , PX16 including a plurality of driving chips 210 as the pixel driving circuits PD and a plurality of light-emitting elements electrically connected to the driving chips 210 may be arranged. Each driving chip 210 may supply a control signal and power to the plurality of light-emitting elements to control a light-emitting operation of the plurality of light-emitting elements.

The substrate 200 may have a shape in which a length of one side is larger than a length of the other side. For example, the substrate 200 may include a long side having a larger length and a short side having a smaller length than that of the long side. The short side may extend in the first direction X of the substrate 200, and the long side may extend in the second direction Y of the substrate 200. However, embodiments of the present disclosure are not limited thereto.

One or more crack detection lines PCDL and PCDR may be disposed in a partial area of the non-display area NA. Each of the one or more crack detection lines PCDL and PCDR may extend along a peripheral area of the display area AA and may detect a defect such as a crack that may occur in the peripheral area of the display area AA. The one or more crack detection lines PCDL and PCDR may extend along at least both opposing sides and a portion of each of upper and lower sides of the display area AA. For example, the one or more crack detection lines PCDL and PCDR may include a first crack detection line PCDL and a second crack detection line PCDR.

The first crack detection line PCDL may extend along a left long side of the substrate 200 and may extend to each of upper and lower left corners and then may extend along a left portion of each of upper and lower short sides. The second crack detection line PCDR may extend along a right long side of the substrate 200 and may extend to each of upper and lower right corners and then may extend along a right portion of each of the upper and lower short sides. The first crack detection line PCDL and the second crack detection line PCDR may be spaced apart from each other.

Each of the first crack detection line PCDL and the second crack detection line PCDR may be disposed to overlap some of the plurality of driving chips 210 at each corner area. The driving chip DC disposed to overlap the first and second crack detection lines PCDL and PCDR in the corner area may be an inactive driving chip 210_n.

The inactive driving chip 210_n may be disposed to overlap the first crack detection line PCDL or the second crack detection line PCDR at the corner area of the substrate 200, and thus may not be electrically connected to at least a portion of the power line or the signal line. Accordingly, the inactive driving chip 210_n may be an unused driving chip that does not control the plurality of light-emitting elements. The inactive driving chip 210_n may include at least eight driving chips arranged along the four corner areas of the substrate 200 among the plurality of driving chips 210. For example, two inactive driving chips 210_n may be disposed in each of the four corner areas of the substrate 200.

The substrate 200 may include a trimming line TRL extending along a peripheral area of the non-display area NA. The trimming line TRL may be a cutting line cut by a laser beam during a scribing process for dividing the substrate 200 into a plurality of display panels 100 (see FIG. 1) as individual units. An area disposed outwardly of the trimming line TRL may be removed in the scribing process.

A plurality of alignment key patterns 101 and 103 may be disposed in the area disposed outwardly of the trimming line TRL. The plurality of alignment key patterns 101 and 103 may include a first alignment key pattern 101 and a second alignment key pattern 103. However, embodiments of the present disclosure are not limited thereto. Since the plurality of alignment key patterns 101 and 103 are disposed in the area disposed outwardly of the trimming line TRL, they may be removed in the scribing process.

The first alignment key pattern 101 may be a pattern for alignment between the display panel 100 and the cover member 155 of FIG. 1. At least one of the plurality of first alignment key patterns 101 may be positioned in the area disposed outwardly of the trimming line TRL facing each corner area of the substrate 200. For example, each first alignment key patterns 101 may be disposed at each of four corner areas of the substrate 200. Thus, the plurality of first alignment key patterns 101 may include four alignment key patterns.

The second alignment key pattern 103 may include various alignment key patterns for aligning components respectively disposed in different layers, such as a plurality of signal lines, contact holes, and a plurality of driving chips disposed on the substrate 200 at correct positions. The second alignment key pattern 103 may include a metal material. Accordingly, the second alignment key pattern 103 may be disposed on the display area AA or the non-display area NA and may be formed at the same time as a time at which a plurality of signal lines including a metal material is formed. However, embodiments of the present disclosure are not limited thereto.

The plurality of driving chips 210 as the pixel driving circuits may be disposed on the display area AA of the substrate 200. For example, the plurality of driving chips 210 may be arranged in a matrix shape. However, embodiments of the present disclosure are not limited thereto.

Each of the plurality of driving chips 210 may include a plurality of driving circuits to drive the plurality of light-emitting elements. One driving chip 210 may be connected to the plurality of first electrodes AND and the plurality of second electrodes CTH respectively connected to the plurality of pixels PX1, PX2, PX3, . . . , PX16. For example, one driving chip 210 may drive the plurality of light-emitting elements arranged in the first row Row 1 to the 16th row Row 16. In other words, one driving chip 210 may be electrically connected to the plurality of light-emitting elements arranged in the first row Row 1 to the 16th row Row 16 via the first electrodes AND and the second electrodes CTH, and may supply a control signal and power thereto via the first electrodes AND and the second electrodes CTH to control the light-emitting operations of the plurality of light-emitting elements.

The display device according to an embodiment of the present disclosure may have an in-cell touch structure in which each of the plurality of second electrodes CTH is used as a touch electrode instead of forming a separate touch electrode. Accordingly, since the separate touch electrode is not formed, a thickness of the display panel may be reduced.

Referring to FIG. 23, when a user's touch operation is performed on the cover member 155, a change in a first capacitance C1 between each of the plurality of second electrodes CTH disposed on the substrate of the display panel 100 and the cover member 155 and a change in a second capacitance C2 between each of the plurality of second electrodes CTH and each of a plurality of signal lines M_SL may be detected and provided to the driving chip 210. In addition, the driving chip 210 may perform a touch control function to provide a control signal based on the touch input to the plurality of light-emitting elements. A ground GND may be disposed to be opposite to the cover member 155 while the plurality of second electrodes CTH are disposed between the cover member and the ground.

A touch sensing scheme of a capacitance substrate may include a self-capacitance operation scheme and a mutual capacitance operation scheme for sensing a touch based on a detecting result of a change in a capacitance between two types of touch sensors.

The display device 1000 according to an embodiment of the present disclosure may perform the touch operation and the touch sensing in the self-capacitance-based touch sensing scheme or may perform the touch operation and the touch sensing in the mutual-capacitance-based touch sensing scheme.

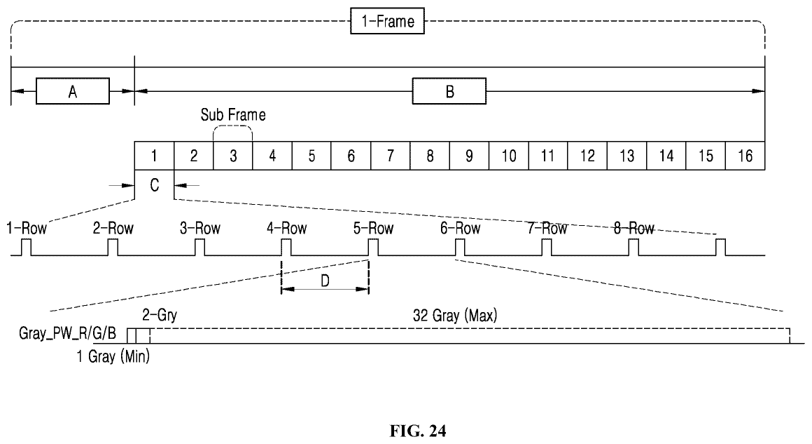

FIG. 24 illustrates an example of a signal waveform diagram when a display device according to an embodiment of the present disclosure operates.

Referring to FIG. 24, the display device according to an embodiment of the present disclosure may perform a light emission operation on one frame basis.

One frame may include a touch period A and a display period B.

One frame may operate at a frequency of, for example, 60 Hz. In this case, the touch period A may operate for a first time duration at a frequency of, for example, 60 Hz, and the display period B may operate for a second time duration larger than the first time duration at a frequency of, for example, 60 Hz. Accordingly, the operation time duration of the touch period A and the operation time duration of the display period B in one frame may be different from each other. For example, the operation time duration of the touch period A may be shorter than the operation time duration of the display period B.

The display period B may include 16 sub-frames.

For example, when, in the display panel, eight light-emitting elements are connected to one anode electrode line as the first electrode, one sub-frame period C may include eight pulse signals 1-Row, 2-Row, 3-Row, 4-Row, 5-Row, 6-Row, 7-Row, and 8-Row. That is, in an embodiment of the present disclosure, eight micro light-emitting elements (LED) may operate during one sub frame.

Accordingly, in an embodiment of the present disclosure, one frame includes 16 sub-frames and one sub-frame includes 8 pulse signals, such that 128 micro light-emitting elements (LED) may operate for one frame.

An embodiment of the present disclosure is not limited thereto. For example, when 16 micro light-emitting elements (LED) are connected to one anode electrode line as the first electrode, one sub-frame period C may include 16 pulse signals. In this case, 256 micro light-emitting elements (LED) may operate for one frame.

One pulse signal (e.g., 5-Row) drives one micro light-emitting element (μLED). One pulse signal period D may include a high signal period and a low signal period. In this regard, a time duration of the low signal period may be larger than a time duration of the high signal period.

In an embodiment of the present disclosure, an operation time duration of the micro light-emitting element (μLED) may be controlled based on a light-emission signal EM applied to the gate electrode of the light-emission transistor TEM.

A micro driver (μDriver) may control an application time duration of the light-emission signal EM based on a pulse width PW. For example, a case in which one pulse signal (e.g., 5-Row) is applied to the gate electrode of the light-emission transistor TEM using one pulse width PW may be referred to as one gray.

In order to control the application time duration of the light-emission signal EM, the micro driver (Driver) may apply one pulse signal (e.g., 5-Row) using the pulse width PW varying from a minimum of 1 Gray (Min) to a maximum of 32 Gray (Max).

One pixel PX may include red (R), green (G), and blue (B) sub-pixels. Each of the plurality of micro light-emitting elements (μLED) may be disposed in the sub-pixel.

Accordingly, the micro driver (Driver) may control a light-emission time duration of the micro light-emitting element (μLED) corresponding to each of red (R), green (G), and blue (B) sub-pixels by applying the pulse signal of which the pulse width PW is adjusted from a minimum of 1 Gray (Min) to a maximum of 32 Gray (Max) to the gate electrode of the light-emission transistor TEM.

According to an embodiment of the present disclosure, the power signals may be directly applied to the driving chip disposed on the display area from the pad of the non-display area, and the data signal and the clock signal may be applied to the driving chips in each of the block areas of the display area

According to an embodiment of the present disclosure, the power signals may be applied to the driving chip of the display area via a dual metal line composed of two metal lines respectively disposed on the different insulating layers.

According to an embodiment of the present disclosure, the power signals, the data signal, and the clock signal may be applied to the driving chip of the display area via a plurality of metal lines respectively disposed on the different insulating layers.

According to an embodiment of the present disclosure, the plurality of metal lines respectively disposed on the different insulating layers may be positioned to vertically overlap the plurality of openings corresponding to the plurality of light-emitting elements, thereby preventing or reducing light incident through the openings from being transmitted to the driving chip.

According to an embodiment of the present disclosure, the data signal and the clock signals may be prevented from being applied to the driving chip of the display area in a delayed manner.

According to an embodiment of the present disclosure, the data signal and the clock signal are applied to the driving chips of each of the block areas of the display area, thereby preventing or reducing the delay in the application time thereof.

According to an embodiment of the present disclosure, the power signals may be applied to the driving chip of the display area via a dual metal line composed of two metal lines respectively disposed on the different insulating layers, thereby preventing the metal lines from being short-circuited with each other, and reducing the resistance of each of the metal lines.

According to an embodiment of the present disclosure, the power consumption for light emission may be reduced as the power signal, the data signal, and the clock signal are reliably applied to the driving chip of a display area.

According to an embodiment of the present disclosure, as the power consumption of the light-emitting element is reduced, a decrease in lifespan of the display device may be prevented or reduced.

According to an embodiment of the present disclosure, the power consumption of the light-emitting element is reduced, and a decrease in the lifespan of the display device is prevented or reduced, thereby providing a long-lifespan and low power display device.

According to an embodiment of the present disclosure, as the power signal, the data signal, and the clock signal are reliably applied to the driving chip of the display area, a defect of a product may be reduced, the lifespan of the display panel may be improved, and the quality of the display device may be improved.

In addition, according to an embodiment of the present disclosure, as the power signal, the data signal, and the clock signal are reliably applied to the driving chip for controlling the light-emitting elements, thereby improving the product quality and securing the product reliability.

The display device according to various aspects and embodiments of the present disclosure may be described as follows.

A first aspect of the present disclosure provides a display device comprising: a substrate including a display area and a non-display area; a plurality of driving chips on the display area of the substrate; a plurality of light-emitting elements on the display area, the plurality of light-emitting elements electrically connected to the plurality of driving chips; and a pad disposed on the non-display area, the pad including a pad electrode electrically connected to the plurality of light-emitting elements, wherein the display area extends in a row direction and a column direction, wherein the display area is divided into a plurality of block areas in each of both opposing sides around a central column virtual line of the display area, wherein both block areas are arranged in the row direction in a symmetrical manner to each other around the central column virtual line, wherein the plurality of block areas are arranged in the column direction, wherein power signals from the pad are directly applied to the plurality of driving chips, wherein a data signal and a clock signal from the pad are applied to the plurality of driving chips of each of the plurality of block areas.

In accordance with some embodiments of the first aspect of the present disclosure, the power signals include a high potential power signal, a low potential power signal, a ground power signal, a precharge power signal, a bias power signal, a reset power signal, an initialization power signal, a reference power signal, and a driving power signal.

In accordance with some embodiments of the first aspect of the present disclosure, the plurality of block areas include: a first group of block areas in one of both opposing sides around the central column virtual line of the display area, the first group of block areas arranged in the column direction; and a second group of block areas in another of both opposing sides around the central column virtual line of the display area, the second group of block areas arranged in the column direction, wherein in each of the first and second groups, the block areas adjacent to each other in the column direction are connected to each other through a connection line.

In accordance with some embodiments of the first aspect of the present disclosure, each of the first and second groups includes first to n-th block areas arranged in the column direction, wherein in each of the first and second groups, the data signal and the clock signal are applied to the first to n-th block areas through respective connection lines in a sequential manner.

In accordance with some embodiments of the first aspect of the present disclosure, the display device further comprises: a printed circuit board on the non-display area; a plurality of first link lines connecting the printed circuit board to the pad; and a plurality of second link lines connecting the pad to the display area.

In accordance with some embodiments of the first aspect of the present disclosure, the display device further comprises: a protective layer on the substrate; a base metal line on the protective layer; a first insulating layer disposed on the protective layer and the base metal line; a first metal line on the first insulating layer; a second insulating layer on the first insulating layer and the first metal line; a second metal line on the second insulating layer; a third insulating layer on the second insulating layer and the second metal line; a third metal line on the third insulating layer; a fourth insulating layer on the third insulating layer and the third metal line; and a fourth metal line on the fourth insulating layer.

In accordance with some embodiments of the first aspect of the present disclosure, the fourth metal line constitutes the pad electrode of the pad and the pad is routed through the base metal line and the first metal line.

In accordance with some embodiments of the first aspect of the present disclosure, the plurality of first link lines are routed through the base metal line, the first metal line, and the third metal line, wherein the power signals are applied through a dual metal line including the base metal line and the first metal line, wherein the data signal and the clock signal are applied through the third metal line.

In accordance with some embodiments of the first aspect of the present disclosure, a bending area is between the pad and the display area, the bending area routed through the base metal line.

In accordance with some embodiments of the first aspect of the present disclosure, a plurality of openings are arranged to correspond to each of the plurality of light-emitting elements, wherein the first metal line to the third metal line are between the plurality of driving chip and the plurality of light-emitting elements and overlap the plurality of openings vertically, respectively.

A second aspect of the present disclosure provides a display device comprising: a substrate including a display area and a non-display area; a plurality of driving chips on the display area of the substrate; a plurality of light-emitting elements are arranged above the plurality of driving chips in the display area, the plurality of light-emitting elements electrically connected to the plurality of driving chips; a pad on the non-display area the pad including a pad electrode electrically connected to the plurality of light-emitting elements; an optical insulating layer on the display area of the substrate and surrounding each of the plurality of light-emitting elements, the optical insulating layer on top of the plurality of light-emitting elements; and a black matrix on the optical insulating layer, the black matrix having a plurality of openings defined therein respectively at positions corresponding to the plurality of light-emitting elements, wherein the display area extends in a row direction and a column direction, wherein the display area is divided into a plurality of block areas in each of both opposing sides around a central column virtual line of the display area, wherein both block areas are arranged in the row direction in a symmetrical manner to each other around the central column virtual line, wherein the plurality of block areas are arranged in the column direction, wherein power signals from the pad are directly applied to the plurality of driving chips, wherein a data signal and a clock signal from the pad are applied to the plurality of driving chips of each of the plurality of block areas.

In accordance with some embodiments of the second aspect of the present disclosure, the display device further comprises: a protective layer on the substrate; a base metal line on the protective layer; a first insulating layer on the protective layer and the base metal line; a first metal line on the first insulating layer; a second insulating layer on the first insulating layer and the first metal line; a second metal line on the second insulating layer; a third insulating layer on the second insulating layer and the second metal line; a third metal line on the third insulating layer; a fourth insulating layer on the third insulating layer and the third metal line; and a fourth metal line on the fourth insulating layer.

In accordance with some embodiments of the second aspect of the present disclosure, a hole is between adjacent portions of the black matrix, wherein each of the first metal line to the third metal line is between the plurality of driving chips and the plurality of light-emitting elements and overlap the hole vertically.

In accordance with some embodiments of the second aspect of the present disclosure, the display device further comprises: a first electrode under each of the plurality of light-emitting elements, the first electrode electrically connected to each of the plurality of light-emitting elements; and a second electrode on the plurality of light-emitting elements and the optical insulating layer, the second electrode electrically connected to the plurality of light-emitting elements.

In accordance with some embodiments of the second aspect of the present disclosure, the optical insulating layer includes: a first optical layer on the display area of the substrate, the first optical layer surrounding each of the plurality of light-emitting elements; a second optical layer on the display area of the substrate, the second optical layer surrounding the first optical layer; and a third optical layer on the display area of the substrate, the third optical layer on the second electrode.

In accordance with some embodiments of the second aspect of the present disclosure, the black matrix fills a contact hole of the second optical layer.

In accordance with some embodiments of the second aspect of the present disclosure, the second electrode is commonly connected to the plurality of light-emitting elements, wherein the second electrode continuously extends on and along the plurality of light-emitting elements and the optical insulating layer.

In accordance with some embodiments of the second aspect of the present disclosure, the first electrode comprises a plurality of conductive layer, including: a first conductive layer on a bank; a second conductive layer on the first conductive layer; a third conductive layer on the second conductive layer; and a fourth conductive layer on the third conductive layer.

In accordance with some embodiments of the second aspect of the present disclosure, each of the plurality of light-emitting elements includes: an anode electrode; a first semiconductor layer on the anode electrode; an active layer on the first semiconductor layer; a second semiconductor layer on the active layer; a cathode electrode on the second semiconductor layer; and an encapsulation film on at least a portion of each of the first semiconductor layer, the active layer, the second semiconductor layer, the anode electrode, and the cathode electrode.

In accordance with some embodiments of the second aspect of the present disclosure, a portion of the black matrix is within a contact hole where the second electrode and the contact electrode are connected to each other in the display area.

Features of various embodiments of the present disclosure may be partially or overall coupled to or combined with each other and may be variously inter-operated with each other and driven technically as those skilled in the art can sufficiently understand. Embodiments of the present disclosure may be carried out independently from each other or may be carried out together in co-dependent relationship.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display device comprising:
a substrate including a display area and a non-display area;
a plurality of driving chips on the display area of the substrate;
a plurality of light-emitting elements on the display area, the plurality of light-emitting elements electrically connected to the plurality of driving chips; and
a pad disposed on the non-display area, the pad including a pad electrode electrically connected to the plurality of light-emitting elements,
wherein the display area extends in a row direction and a column direction,
wherein the display area is divided into a plurality of block areas in each of both opposing sides around a central column virtual line of the display area,
wherein at least two block areas in the plurality of block areas are arranged in the row direction in a symmetrical manner to each other around the central column virtual line,
wherein the plurality of block areas are further arranged in the column direction,
wherein power signals from the pad are directly applied to the plurality of driving chips,
wherein a data signal and a clock signal from the pad are applied to the plurality of driving chips of each of the plurality of block areas.

2. The display device of claim 1, wherein the power signals include a high potential power signal, a low potential power signal, a ground power signal, a precharge power signal, a bias power signal, a reset power signal, an initialization power signal, a reference power signal, and a driving power signal.

3. The display device of claim 1, wherein the plurality of block areas include:
a first group of block areas in one of both opposing sides around the central column virtual line of the display area, the first group of block areas arranged in the column direction; and
a second group of block areas in another of both opposing sides around the central column virtual line of the display area, the second group of block areas arranged in the column direction,
wherein in each of the first group of block areas and the second group of block areas, block areas adjacent to each other in the column direction are connected to each other through a connection line.

4. The display device of claim 3, wherein each of the first group of block areas and the second group of block areas includes first to n-th block areas arranged in the column direction,
wherein in each of the first group of block areas and the second group of block areas, the data signal and the clock signal are applied to the first to n-th block areas through respective connection lines in a sequential manner.

5. The display device of claim 1, wherein the display device further comprises:
a printed circuit board on the non-display area;
a plurality of first link lines connecting the printed circuit board to the pad; and
a plurality of second link lines connecting the pad to the display area.

6. The display device of claim 5, wherein the display device further comprises:
a protective layer on the substrate;
a base metal line on the protective layer;
a first insulating layer on the protective layer and the base metal line;
a first metal line on the first insulating layer;
a second insulating layer on the first insulating layer and the first metal line;
a second metal line on second insulating layer;
a third insulating layer disposed on the second insulating layer and the second metal line;
a third metal line on the third insulating layer;
a fourth insulating layer on the third insulating layer and the third metal line; and
a fourth metal line on the fourth insulating layer.

7. The display device of claim 6, wherein the fourth metal line constitutes the pad electrode of the pad and the pad is routed through the base metal line and the first metal line.

8. The display device of claim 6, wherein the plurality of first link lines are routed through the base metal line, the first metal line, and the third metal line,
wherein the power signals are applied through a dual metal line including the base metal line and the first metal line,
wherein the data signal and the clock signal are applied through the third metal line.

9. The display device of claim 6, wherein a bending area is between the pad and the display area, the bending area routed through the base metal line.

10. The display device of claim 6, wherein a plurality of openings are arranged to correspond one-to-one each of the plurality of light-emitting elements,
wherein the first metal line to the third metal line are between the plurality of driving chips and the plurality of light-emitting elements and overlap the plurality of openings vertically, respectively.

11. A display device comprising:
a substrate including a display area and a non-display area;
a plurality of driving chips on the display area of the substrate;
a plurality of light-emitting elements arranged above the plurality of driving chips in the display area, the plurality of light-emitting elements electrically connected to the plurality of driving chips;
a pad on the non-display area the pad including a pad electrode electrically connected to the plurality of light-emitting elements;
an optical insulating layer on the display area of the substrate and surrounding each of the plurality of light-emitting elements, the optical insulating layer on the plurality of light-emitting elements; and
a black matrix on the optical insulating layer, the black matrix having a plurality of openings defined therein respectively at positions corresponding to the plurality of light-emitting elements,
wherein the display area extends in a row direction and a column direction,
wherein the display area is divided into a plurality of block areas in each of both opposing sides around a central column virtual line of the display area,
wherein at least two block areas in the plurality of block areas are arranged in the row direction in a symmetrical manner to each other around the central column virtual line,
wherein the plurality of block areas are further arranged in the column direction,
wherein power signals from the pad are directly applied to the plurality of driving chips,
wherein a data signal and a clock signal from the pad are applied to the plurality of driving chips of each of the plurality of block areas.

12. The display device of claim 11, wherein the display device further comprises:
a protective layer on the substrate;
a base metal line on the protective layer;
a first insulating layer on the protective layer and the base metal line;
a first metal line on the first insulating layer;
a second insulating layer on the first insulating layer and the first metal line;
a second metal line on the second insulating layer;
a third insulating layer on the second insulating layer and the second metal line;
a third metal line on the third insulating layer;
a fourth insulating layer on the third insulating layer and the third metal line; and
a fourth metal line on the fourth insulating layer.

13. The display device of claim 12, wherein a hole is between adjacent portions of the black matrix,
wherein each of the first metal line to the third metal line is between the plurality of driving chips and the plurality of light-emitting elements and overlap the hole vertically.

14. The display device of claim 11, wherein the display device further comprises:
a first electrode under each of the plurality of light-emitting elements, the first electrode electrically connected to each of the plurality of light-emitting elements; and
a second electrode on the plurality of light-emitting elements and the optical insulating layer, the second electrode electrically connected to the plurality of light-emitting elements.

15. The display device of claim 14, wherein the optical insulating layer includes:
a first optical layer on the display area of the substrate, the first optical layer surrounding each of the plurality of light-emitting elements;
a second optical layer on the display area of the substrate, the second optical layer surrounding the first optical layer; and
a third optical layer on the display area of the substrate, the third optical layer on the second electrode.

16. The display device of claim 15, wherein the black matrix fills a contact hole of the second optical layer.

17. The display device of claim 15, wherein the second electrode is commonly connected to the plurality of light-emitting elements,
wherein the second electrode continuously extends on and along the plurality of light-emitting elements and the optical insulating layer.

18. The display device of claim 14, wherein the first electrode comprises a plurality of conductive layers including:
a first conductive layer on a bank;
a second conductive layer on the first conductive layer;
a third conductive layer on the second conductive layer; and
a fourth conductive layer on the third conductive layer.

19. The display device of claim 11, wherein each of the plurality of light-emitting elements includes:
an anode electrode;
a first semiconductor layer on the anode electrode;
an active layer on the first semiconductor layer;
a second semiconductor layer on the active layer;
a cathode electrode on the second semiconductor layer; and
an encapsulation film on at least a portion of each of the first semiconductor layer, the active layer, the second semiconductor layer, the anode electrode, and the cathode electrode.

20. The display device of claim 14, wherein a portion of the black matrix is within a contact hole where the second electrode and a contact electrode are connected to each other in the display area.
